(19) United States
(12) Patent Application Publication
(10) Pub. No.: US 2023/0232642 A1
(43) Pub. Date: Jul. 20, 2023

(54) PHOTOELECTRIC CONVERSION ELEMENT, PHOTOELECTRIC CONVERSION ELEMENT MODULE, ELECTRONIC DEVICE, POWER SUPPLY MODULE, AND METHOD FOR PRODUCING PHOTOELECTRIC CONVERSION ELEMENT

(71) Applicants: Takaya ITO, Shizuoka (JP); Ryota ARAI, Shizuoka (JP); Tomoya HIRANO, Tokyo (JP)

(72) Inventors: Takaya ITO, Shizuoka (JP); Ryota ARAI, Shizuoka (JP); Tomoya HIRANO, Tokyo (JP)

(21) Appl. No.: 18/010,463

(22) PCT Filed: Jun. 29, 2021
(86) PCT No.: PCT/IB2021/055780

§ 371 Date: Dec. 15, 2022

(30) Foreign Application Priority Data
Jul. 8, 2020 (JP) 2020-117458

(51) Int. Cl. H10K 30/85; H10K 30/50; H10K 30/86; H10K 39/12; H10K 71/20

(52) U.S. Cl. CPC H10K 30/85; H10K 30/50; H10K 30/86; H10K 39/12; H10K 71/20; H10K 2102/351

(57) ABSTRACT

A photoelectric conversion element includes a base, a first electrode on or above the base, an electron-transporting layer on or above the first electrode, a photoelectric conversion layer on or above the electron-transporting layer, a hole-transporting layer on or above the photoelectric conversion layer, and a second electrode on or above the hole-transporting layer. The photoelectric conversion element has a penetration portion penetrating the electron-transporting layer and the photoelectric conversion layer. The photoelectric conversion element includes, in the penetration portion, a material of the hole-transporting layer and a material of the second electrode.

### TECHNICAL FIELD

The present disclosure relates to a photoelectric conversion element, a photoelectric conversion element module, an electronic device, a power supply module, and a method for producing a photoelectric conversion element.

### BACKGROUND ART

In recent years, realization of an Internet of Things (IoT) society has been expected where all things are connected to the Internet to allow for comprehensive control. Such an IoT society requires to attach many sensors to various things to obtain data. To do this, power supplies are required to drive many sensors. Use of wirings or electricity storage cells for many sensors is not practical. Accompanied with the increased needs in the society for reduction in environmental load, energy harvesting elements have been expected for power supply.

Among others, photoelectric conversion elements have attracted attention as elements able to supply electricity anywhere as long as light is there. In particular, a photoelectric conversion element having flexibility is required to be highly efficient, and also is expected to be able to contour various curved surfaces and to be adapted for wearable devices. Results of studies on potential for wearable devices are reported (see, for example, NPLs 1 and 2).

In general, an organic thin-film solar cell is promising as a highly efficient energy harvesting element having flexibility. One proposal is a photoelectric conversion element having a transparent base film as a base (see, for example, PTL 1).

The photoelectric conversion element in a typical organic thin-film solar cell often has a structure including a supporting substrate and a first electrode, an electron-transporting layer, a photoelectric conversion layer, a hole-transporting layer, and a second electrode, which are sequentially stacked on or above the supporting substrate. In order to allow the photoelectric conversion element to increase in power output, a module structure may be used where two or more photoelectric conversion elements are produced on the same substrate and coupled in series to each other. In order to couple in series the second electrode as the uppermost layer of the photoelectric conversion element to the first electrode of the adjacent photoelectric conversion element, a penetration portion may be formed in a part for coupling. When the second electrode is coupled to the first electrode via a penetration portion formed, the second electrode is extended so as to be coupled to the first electrode and is brought into contact with the first electrode. To do this, formation of a protective layer has been proposed to avoid contact of the second electrode with the layers other than the first electrode (see, for example, PTL 2).

### CITATION LIST

### Patent Literature

### [PTL 1]

Japanese Unexamined Patent Application Publication No. 2014-220333

### [PTL 2]

Japanese Unexamined Patent Application Publication No. 2014-192196

### Non Patent Literature

### [NPL 1]

Applied Physics letters 108, 253301 (2016)

### [NPL 2]

Japanese Journal of Applied Physics 54, 071602 (2015)

### SUMMARY OF INVENTION

### Technical Problem

The present disclosure has an object to provide a photoelectric conversion element having a simple structure and exhibiting photoelectric conversion characteristics comparable to those of the existing photoelectric conversion elements.

### Solution to Problem

According to one aspect of the present disclosure, a photoelectric conversion element includes a base, a first electrode on or above the base, an electron-transporting layer on or above the first electrode, a photoelectric conversion layer on or above the electron-transporting layer, a hole-transporting layer on or above the photoelectric conversion layer, and a second electrode on or above the hole-transporting layer. The photoelectric conversion element has a penetration portion penetrating the electron-transporting layer and the photoelectric conversion layer. The photoelectric conversion element includes, in the penetration portion, a material of the hole-transporting layer and a material of the second electrode.

### Advantageous Effects of Invention

The present disclosure can provide a photoelectric conversion element having a simple structure and exhibiting photoelectric conversion characteristics comparable to those of the existing photoelectric conversion elements.

### BRIEF DESCRIPTION OF DRAWINGS

The accompanying drawings are intended to depict example embodiments of the present invention and should not be interpreted to limit the scope thereof. The accompanying drawings are not to be considered as drawn to scale unless explicitly noted. Also, identical or similar reference numerals designate identical or similar components throughout the several views.

FIG. 1A is a schematic view illustrating one example of a production step in a method of the present disclosure for producing a photoelectric conversion element module.

FIG. 1B is a schematic view illustrating another example of a production step in a method of the present disclosure for producing a photoelectric conversion element module.

FIG. 1C is a schematic view illustrating another example of a production step in a method of the present disclosure for producing a photoelectric conversion element module.

FIG. 1D is a schematic view illustrating another example of a production step in a method of the present disclosure for producing a photoelectric conversion element module.

FIG. 1E is a schematic view illustrating another example of a production step in a method of the present disclosure for producing a photoelectric conversion element module.

FIG. 1F is a schematic view illustrating another example of a production step in a method of the present disclosure for producing a photoelectric conversion element module.

FIG. 1G is a schematic view illustrating another example of a production step in a method of the present disclosure for producing a photoelectric conversion element module.

FIG. 1H is a schematic view illustrating another example of a production step in a method of the present disclosure for producing a photoelectric conversion element module.

FIG. 1I is a schematic view illustrating another example of a production step in a method of the present disclosure for producing a photoelectric conversion element module.

FIG. 1J is a schematic view illustrating another example of a production step in a method of the present disclosure for producing a photoelectric conversion element module.

FIG. 1K is a schematic view illustrating another example of a production step in a method of the present disclosure for producing a photoelectric conversion element module.

FIG. 1L is a schematic view illustrating another example of a production step in a method of the present disclosure for producing a photoelectric conversion element module.

FIG. 1M is a schematic view illustrating another example of a production step in a method of the present disclosure for producing a photoelectric conversion element module.

FIG. 2 is a block diagram of a mouse for a personal computer as one example of an electronic device of the present disclosure.

FIG. 3 is a schematic external view illustrating one example of the mouse illustrated in FIG. 2.

FIG. 4 is a block diagram of a keyboard for a personal computer as one example of an electronic device of the present disclosure.

FIG. 5 is a schematic external view illustrating one example of the keyboard illustrated in FIG. 4.

FIG. 6 is a schematic external view illustrating another example of the keyboard illustrated in FIG. 4.

FIG. 7 is a block diagram of a sensor as one example of an electronic device of the present disclosure.

FIG. 8 is a block diagram of a turntable as one example of an electronic device of the present disclosure.

FIG. 9 is a block diagram illustrating one example of an electronic device of the present disclosure.

FIG. 10 is a block diagram illustrating one example where a power supply integrated circuit (IC) is further incorporated into the electronic device illustrated in FIG. 9.

FIG. 11 is a block diagram illustrating one example where an electricity storage device is further incorporated into the electronic device illustrated in FIG. 10.

FIG. 12 is a block diagram illustrating one example of a power supply module of the present disclosure.

FIG. 13 is a block diagram illustrating one example where an electricity storage device is further incorporated into the power supply module illustrated in FIG. 12.

### DESCRIPTION OF EMBODIMENTS

The terminology used herein is for the purpose of describing particular embodiments only and is not intended to be limiting of the present invention. As used herein, the singular forms “a”, “an” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

(Photoelectric Conversion Element)

The photoelectric conversion element of the present disclosure includes a base, a first electrode on or above the base, an electron-transporting layer on or above the first electrode, a photoelectric conversion layer on or above the electron-transporting layer, a hole-transporting layer on or above the photoelectric conversion layer, and a second electrode on or above the hole-transporting layer. The photoelectric conversion element has a penetration portion penetrating the electron-transporting layer and the photoelectric conversion layer. The photoelectric conversion element includes, in the penetration portion, a material of the hole-transporting layer and a material of the second electrode. If necessary, the photoelectric conversion element further includes an insulating layer, a sealing member, a UV cut layer, and other layers.

The photoelectric conversion element of the present disclosure includes a base, a first electrode on or above the base, an electron-transporting layer on or above the first electrode, a photoelectric conversion layer on or above the electron-transporting layer, a hole-transporting layer on or above the photoelectric conversion layer, and a second electrode on or above the hole-transporting layer. The second electrode is extended so as to penetrate the hole-transporting layer and the photoelectric conversion layer in the stacking direction. The second electrode, which is extended in the stacking direction, and the first electrode are coupled to each other via a hole-transporting material in contact with the electron-transporting layer. If necessary, the photoelectric conversion element further includes an insulating layer, a sealing member, a UV cut layer, and other layers.

In the present specification, a “photoelectric conversion element” refers to an element to convert light energy to electric energy or an element to convert electric energy to light energy. Specifically, the photoelectric conversion element is, for example, a solar cell or a photodiode.

In the present specification, a “base” may also be referred to as a “substrate”.

Hitherto, in order to allow the photoelectric conversion element to increase in power output, for example, two or more photoelectric conversion elements have been produced on the same substrate and coupled in series to each other to form a module structure. In this case, the layers on or above the first electrode of the photoelectric conversion element are removed, and a through hole is provided so that the second electrode can electrically contact the first electrode. In such related art, when the second electrode is disposed in the through hole, a protective (resin) layer is formed so as to avoid contact of the second electrode with the layers other than the first electrode. As a result, disadvantageously, the structure becomes complicated and the production process becomes cumbersome. In order to develop excellent photoelectric conversion characteristics, no high-resistant substance is required to be in a portion where the second electrode and the first electrode are coupled.

The present inventors conducted intensive studies and have found that when a photoelectric conversion element, which includes a base, a first electrode on or above the base, an electron-transporting layer on or above the first electrode, a photoelectric conversion layer on or above the electron-transporting layer, a hole-transporting layer on or above the photoelectric conversion layer, and a second electrode on or above the hole-transporting layer, is provided with a penetration portion penetrating the electron-transporting layer and the photoelectric conversion layer and includes, in the penetration portion, a material of the hole-transporting layer and a material of the second electrode, the photoelectric conversion element has a simple structure and exhibits photoelectric conversion characteristics comparable to those of the existing photoelectric conversion elements.

The present inventors have also found that when the hole-transporting layer is disposed so as to contact the layers on or above the first electrode (e.g., the electron-transporting layer and the photoelectric conversion layer) and the second electrode is disposed as a layer on or above the hole-transporting layer, the hole-transporting layer serves as a protective layer that prevents contact of the second electrode and the first electrode with the other layers on or above the second electrode and the first electrode, to maintain photoelectric conversion characteristics comparable to those of the existing photoelectric conversion elements. Specifically, the present inventors have found that when a penetration portion is provided in the layers on or above the first electrode (e.g., the electron-transporting layer and the photoelectric conversion layer) so as to be able to electrically couple the first electrode and the second electrode to each other, and the hole-transporting layer and the second electrode are provided on or above the first electrode, the hole-transporting layer and the second electrode can be present in the penetration portion. In the penetration portion, the hole-transporting layer is in contact with the second electrode, the first electrode, and the layers on or above the first electrode (e.g., the electron-transporting layer and the photoelectric conversion layer).

The present inventors have also found that when the second electrode is extended so as to penetrate the hole-transporting layer and the photoelectric conversion layer in the stacking direction, and a region of the second electrode, the region being extended in the stacking direction, and the first electrode are coupled to each other via a hole-transporting material (i.e., a material to form the hole-transporting layer) in contact with the electron-transporting layer, the photoelectric conversion element has a simple structure and exhibits photoelectric conversion characteristics comparable to those of the existing photoelectric conversion elements.

The stacking direction refers to a direction perpendicular to the plane direction of each of the layers in the photoelectric conversion element. Coupling refers not only to physical contact but also to electrical coupling to such an extent as to be able to exhibit the effects of the present disclosure.

In the present disclosure, the layer includes not only a structure of two or more films stacked but also a single film (monolayer).

—Penetration Portion—

The penetration portion is a region penetrating the electron-transporting layer and the photoelectric conversion layer, which will be described below.

The penetration portion preferably penetrates the below-described electron-transporting layer and photoelectric conversion layer in the stacking direction.

The penetration portion includes in the interior thereof (hereinafter referred to as a penetration portion interior) a material of the hole-transporting layer and a material of the second electrode, which will be described below.

In the penetration portion interior, the material of the hole-transporting layer and the material of the second electrode are preferably included as respective layers. When the material of the hole-transporting layer and the material of the second electrode form respective layers in the penetration portion interior, they may be referred to as simply as the hole-transporting layer and the second electrode. The average thickness of the hole-transporting layer and the second electrode in the penetration portion interior is preferably 200 nm or less.

It is preferable in the penetration portion interior that the hole-transporting layer be disposed under the second electrode so that the hole-transporting layer is located so as to avoid contact of the second electrode with the electron-transporting layer and the photoelectric conversion layer. Specifically, it is preferable in the penetration portion interior that the hole-transporting layer be disposed so as to contact the electron-transporting layer and the photoelectric conversion layer.

In the penetration portion interior, the hole-transporting layer may be in contact with the electron-transporting layer, the photoelectric conversion layer, and the first electrode.

The present inventors have found that even by coupling the second electrode and the first electrode to each other via the hole-transporting layer, which is the underlying layer of the second electrode, when electrically coupling the first electrode and the second electrode to each other, the photoelectric conversion element exhibits photoelectric conversion characteristics comparable to those of the existing photoelectric conversion elements.

A method for forming the penetration portion is not particularly limited and may be appropriately selected depending on the intended purpose as long as the method allows for penetration through the below-described electron-transporting layer and photoelectric conversion layer that are formed on or above the base. Examples of the method include, but are not limited to, laser deletion and mechanical scribing.

<Base>

The base is not particularly limited and may be appropriately selected depending on the intended purpose. Examples of the base include, but are not limited to, films having transparency and flexibility and glass films having no flexibility but having high planarity. Examples of the film having transparency and flexibility include, but are not limited to, films of, for example, polyester such as polyethylene terephthalate, polycarbonate, polyimide, polymethyl methacrylate, polysulfone, or polyether ether ketone. A glass thin film having an average thickness of 200 micrometers or less is also included. Of these, a polyester film, a polyimide film, and a glass thin film are preferable in terms of ease of production and cost. When a base made of resin is used, the base preferably includes a gas barrier layer. The gas barrier layer is a layer having a function of preventing permeation of moisture and oxygen. The gas barrier layer is not particularly limited and may be appropriately selected depending on the intended purpose as long as it has such a function. Examples thereof include, but are not limited to, aluminum-coated resin bases and those disclosed in JP-5339655-B and JP-2014-60351-A.

Examples of the glass film having no flexibility but having high planarity include, but are not limited to, inorganic transparent crystal bodies.

<First Electrode>

The first electrode is an electrode disposed on or above the base.

The first electrode is not particularly limited and may be appropriately selected depending on the intended purpose. It is, for example, a transparent conductive film that is transparent to visible light. The first electrode may be a stack including a metal thin-film layer between transparent conductive films. At least one of the first electrode and the below-described second electrode is preferably an electrode that is transparent to visible light. In this case, the other electrode may be transparent or opaque.

The materials of the transparent conductive films that sandwich the metal thin-film layer therebetween may be identical to or different from each other.

Examples of the material used for the transparent conductive film, but are not limited to, tin-doped indium oxide (ITO), zinc-doped indium oxide (IZO), zinc oxide (ZnO), fluorine-doped tin oxide (hereinafter referred to as “FTO”), aluminum-doped zinc oxide (AZO), gallium-doped zinc oxide (GZO), and tin oxide (SnO₂). Of these, ITO, IZO, and AZO are preferable. In order to maintain certain hardness, the electrode that is transparent to visible light is preferably provided on the substrate formed of a material that is transparent to visible light. An integrated product of the electrode and the substrate may also be used. Examples thereof include, but are not limited to, FTO-coated glass films, ITO-coated glass films, zinc oxide:aluminum-coated glass films, FTO-coated transparent plastic films, and ITO-coated transparent plastic films.

The material of the first electrode may be, for example, a metal lead wire for the purpose of reducing the resistance of the substrate. Examples of the material of the metal lead wire include, but are not limited to, metals such as aluminum, copper, silver, gold, platinum, and nickel. The metal lead wire may be provided on the substrate by, for example, vapor deposition, sputtering, or bonding, and ITO or FTO may be provided on the metal lead wire.

Regarding the structure of the first electrode, the first electrode may be a metal electrode on a substrate such as a glass substrate, where the metal electrode is structured to have a mesh or stripe shape through which light can transmit. Also, the first electrode may be carbon nanotube, graphene, etc. stacked on the substrate to such an extent as to ensure transparency. One of these may be used alone or two or more of these may be used as a mixture or stack thereof.

When the first electrode or the second electrode is an opaque electrode, the opaque electrode is formed of a metal such as platinum, gold, silver, copper, or aluminum, or of graphite. The average thickness of the opaque electrode is not particularly limited. One of these may be used alone or two or more of these may be used as a stacked structure thereof.

The average thickness of the first electrode is preferably 5 nm or more but 10 micrometers or less and more preferably 50 nm or more but 1 micrometer or less.

The sheet resistance of the transparent electrode is preferably 50 Ω/sq. or less, more preferably 30 Ω/sq., and further preferably 20 Ω/sq.

The transparent electrode preferably has high transmittance in terms of conversion efficiency. The degree of transmittance is preferably 60% or higher and more preferably 70% or higher. The upper limit thereof is not particularly limited and may be appropriately selected depending on the intended purpose. It is preferably 90% or lower.

The first electrode can be formed by, for example, various kinds of wet film formation, dry film formation such as vapor deposition or sputtering, or printing.

<Electron-Transporting Layer>

The electron-transporting layer is between the first electrode and the photoelectric conversion layer.

The electron-transporting layer has the penetration portion. The position of the penetration portion in the electron-transporting layer is not particularly limited and may be appropriately selected depending on the intended purpose. It is preferable in a plan view that the position of the penetration portion in the electron-transporting layer be the same as the position of the penetration portion in the photoelectric conversion layer.

The electron-transporting layer is responsible for transportation of electrons and also has a function of blocking holes (hole-blocking function).

The electron-transporting layer preferably includes particles of a metal oxide. The electron-transporting layer can be formed by coating of a dispersion liquid of metal oxide particles, followed by drying.

The solvent for coating of the electron-transporting layer is not particularly limited and may be appropriately selected depending on the intended purpose. Examples of the solvent include, but are not limited to, alcohol solvents such as methanol, ethanol, isopropanol, 1-propanol, 2-methoxyethanol, 2-ethoxyethanol, or mixtures thereof.

Examples of the metal in the metal oxide include, but are not limited to, titanium, zinc, lithium, and tin.

As the metal oxide, ITO, FTO, ATO, AZO, GZO, etc. can be used in addition to the oxides of the above metals. In forming the electron-transporting layer, alkoxides of metals may be used as materials to form the metal oxides.

Examples of preferable metal oxides as the above metal oxide include, but are not limited to, those having zinc oxide, such as zinc oxide doped to increase conductivity. Examples of the zinc oxide doped to increase conductivity include, but are not limited to, aluminum-doped zinc oxide, gallium-doped zinc oxide, and lithium-doped zinc oxide.

The average particle diameter (D) of particles of the metal oxide is preferably 1 nm or more but 50 nm or less and more preferably 5 nm or more but 20 nm or less.

The average thickness of the electron-transporting layer is preferably 1 nm or more but 300 nm or less and more preferably 10 nm or more but 150 nm or less.

The average particle diameter (D) of particles of the metal oxide can be measured in the following manner.

Specifically, a solution of the particles of the metal oxide is transferred to a nebulizer made of glass using a micropipette. The solution is sprayed from the nebulizer to a grid for TEM provided with a collodion membrane, followed by applying a solvent. The PVD method is used to subject the grid to vapor deposition of carbon. An electron microscope is used to obtain an image of the metal oxide particles. The obtained image is subjected to image processing, and the particle diameters of the metal oxide particles are measured.

In one possible alternative method, the cross-section of the photoelectric conversion element is observed with a scanning transmission electron microscope (TEM), and image processing is used for particle recognition to measure the particle diameters of the metal oxide particles. Another possible alternative method is measuring the particle size distribution by, for example, the laser diffraction/scattering method. A method of exposing the cross-section, observation with the TEM, and measurement of the particle size distribution can be performed by respective methods that are hitherto known.

The average particle diameter of the metal oxide particles in the present disclosure is determined by measuring and averaging the particle diameters of at least 100 metal oxide particles that are randomly selected.

A preferable embodiment of the electron-transporting layer is, for example, an embodiment where the electron-transporting layer includes a first electron-transporting layer containing the particles of the metal oxide and a second electron-transporting layer (intermediate layer) between the first electron-transporting layer and the photoelectric conversion layer.

The second electron-transporting layer (intermediate layer) preferably contains an amine compound represented by General Formula (1) below. When the second electron-transporting layer (intermediate layer) contains an amine compound represented by General Formula (1) below, it is possible to enhance photoelectric conversion characteristics.

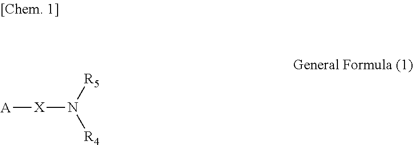

In the above General Formula (1), R₄ and R₅ each represent a substituted or non-substituted alkyl group having from 1 through 4 carbon atoms, X represents a divalent aromatic group having from 6 through 14 carbon atoms or an alkyl group having from 1 through 4 carbon atoms, R₄ and R₅ may be bonded to form a ring, and A represents one of the substituents having structural formulas below.

—COOH

—P(═O)(OH)₂

—Si(OH)₃ [Chem. 2]

<Photoelectric Conversion Layer>

The photoelectric conversion layer is on or above the electron-transporting layer.

The photoelectric conversion layer has the penetration portion. The position of the penetration portion in the photoelectric conversion layer is not particularly limited and may be appropriately selected depending on the intended purpose. It is preferable in a plan view that the position of the penetration portion in the photoelectric conversion layer be the same as the position of the penetration portion in the electron-transporting layer.

The photoelectric conversion layer preferably contains at least two kinds of organic materials and if necessary, further contains other components.

When the photoelectric conversion layer contains two or more kinds of organic materials, preferably, at least one of the organic materials is an electron-donating organic material and another or the other organic material is an electron-accepting organic material. The electron-donating organic material may be called a p-type organic semiconductor material, and the electron-accepting organic material may be called an n-type organic semiconductor material. The photoelectric conversion layer preferably has a bulk hetero structure in which these materials are mixed.

The kind of the electron-donating organic material is not particularly limited and may be appropriately selected depending on the intended purpose. The electron-donating organic material is preferably a π-electron conjugated compound having a highest occupied molecular orbital (HOMO) level of 5.1 eV or higher but 5.5 eV or lower.

Specific examples of the electron-donating organic material include, but are not limited to, conjugated polymers obtained by coupling various aromatic derivatives (e.g., thiophene, fluorene, carbazole, thienothiophene, benzodithiophene dithienosilole, quinoxaline, and benzothiadiazole) and porphyrins and phthalocyanines that are low-molecular-weight conjugated compounds having clearly defined molecular weights. Further examples include, but are not limited to, organic materials such as donor-acceptor conjugated materials each having an electron-donating site and an electron-accepting site in a molecule thereof.

Of these electron-donating organic materials, more preferable are electron-donating organic materials of electron donors (P-type semiconductors) of low-molecular-weight conjugated compounds having a number average molecular weight of 10,000 or lower. The above number average molecular weight is more preferably 5,000 or lower.

Specific examples of the at least one organic material of the two or more kinds of the organic materials contained in the photoelectric conversion layer include, but are not limited to, compounds represented by General Formula (2) below. The compounds represented by General Formula (2) below are, in particular, specific examples of electron donors (P-type semiconductors) that are electron-donating organic materials, are organic materials having a highest occupied molecular orbital (HOMO) level of 5.1 eV or higher but 5.5 eV or lower, and have a number average molecular weight of 10,000 or lower.

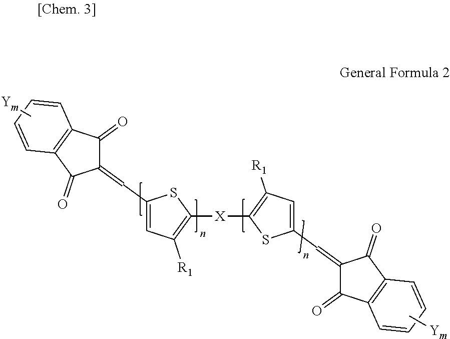

In the above General Formula (2), R₁ represents an alkyl group having from 2 through 8 carbon atoms, n represents an integer of 1 or 2, X represents General Formula (3) below or General Formula (4) below, Y represents a halogen atom, and m represents an integer of from 0 through 4.

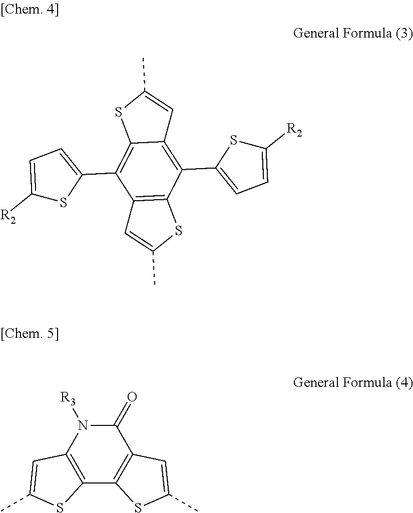

In the above General Formula (3) and the above General Formula (4), R₂ and R₃ each represent a straight chain or branched alkyl group. The straight chain or branched alkyl group of the R₂ or R₃ is preferably an alkyl group having 2 or more but 30 or less carbon atoms.

When the photoelectric conversion layer contains three or more kinds of organic materials, at least two of the organic materials are electron-donating organic materials. Preferably, one of the electron-donating organic materials has a highest occupied molecular orbital (HOMO) level of 5.1 eV or higher but 5.5 eV or lower and a number average molecular weight (Mn) of 10,000 or lower, and another or the other of the electron-donating organic materials is an organic material having a highest occupied molecular orbital (HOMO) level of 5.1 eV or higher but 5.5 eV or lower, where the organic material has a repeating unit and has a number average molecular weight (Mn) of 10,000 or higher.

The kind of the electron-accepting organic material, which is the another or other organic material, is not particularly limited and may be appropriately selected depending on the intended purpose. The electron-accepting organic material is preferably a π-electron conjugated compound having a lowest unoccupied molecular orbital (LUMO) of from 3.5 eV through 4.5 eV.

Examples of the above another or other organic material include, but are not limited to, electron acceptors (N-type semiconductors) such as fullerene or derivatives thereof, naphthalene tetracarboxylic acid imide derivatives, and perylene tetracarboxylic acid imide derivatives. Of these, fullerene derivatives are more preferable.

Specific examples of the fullerene derivatives include, but are not limited to, C60, phenyl-C61-methyl butyrate (fullerene derivatives described as PCBM, [60]PCBM, or PC61BM in some documents), C70, phenyl-C71-methyl butyrate (fullerene derivatives described as PCBM, [70]PCBM, or PC71BM in some documents), and fullerene derivatives described in the web site of DAIKIN INDUSTRIES, Ltd.

The average thickness of the photoelectric conversion layer is preferably from 50 nm or more but 400 nm or less and more preferably 60 nm or more but 250 nm or less. When the average thickness thereof is 50 nm or more, it is possible to effectively prevent a problem that the photoelectric conversion layer absorbs a small amount of light to result in an insufficient number of generated carriers. When the average thickness thereof is 400 nm or less, it is effectively possible to prevent reduction in transfer efficiency of carriers generated by light absorption.

The average thickness (T) of the photoelectric conversion layer can be measured in the following manner.

Specifically, the photoelectric conversion layer is formed on a substrate and is randomly wiped off with a solvent at nine points. The level differences at the nine points, where the photoelectric conversion layer has been wiped off, are measured with DEKTAK available from Bruker Corporation. The average value of the nine values is defined as the average thickness (T) of the photoelectric conversion layer.

Alternatively, the cross-section of the photoelectric conversion layer can be observed with a scanning electron microscope (SEM) or a transmission electron microscope (TEM) to measure the average thickness of the photoelectric conversion layer.

In the present disclosure, the organic materials may be sequentially formed into layers to form a planar junction interface. In order to enlarge the area of the junction interface, preferably, these organic materials are three-dimensionally mixed to form a bulk heterojunction.

In one possible method for forming the bulk heterojunction, in the case of using organic materials having high solubility, those organic materials are dissolved in a solvent to prepare a solution in which the organic materials are mixed together at the molecular level. The prepared solution is coated, followed by drying to remove the solvent, to form the bulk heterojunction. Additionally, a heating treatment may be performed to optimize the aggregation states of the respective semiconductors.

Also in the case of using organic materials having low solubility, the organic materials are dissolved or dispersed in a solvent to prepare a solution, and the prepared solution can be coated to form a mixed layer. Additionally, a heating treatment may be performed to optimize the aggregation states of the respective semiconductors.

Examples of a method for forming a thin film of the organic material include, but are not limited to, spin coating, blade coating, slit die coating, screen printing coating, bar coater coating, mold coating, the print transfer method, the dip pull method, the inkjet method, the spray method, and the vacuum vapor deposition method. An actually used method can be appropriately selected from these methods depending on the properties of an organic material thin film intended to be produced; i.e., in consideration of, for example, thickness control and orientation control.

For spin coating, for example, it is preferable to use a solution containing the P-type semiconductor material having the structure represented by the above General Formula (2) and the N-type semiconductor material at a concentration of 5 mg/mL or more but 40 mg/mL or less.

Here, the concentration refers to the mass of the P-type semiconductor material having the structure represented by the above General Formula (2) and the N-type semiconductor material relative to the volume of a solution containing the P-type semiconductor material having the structure represented by the above General Formula (2) and the N-type semiconductor material. In the range of the above concentration, it is possible to easily produce a uniform photoelectric conversion layer.

In order to remove the organic solvent from the produced photoelectric conversion layer, an annealing treatment may be performed under reduced pressure or in an inert atmosphere (in a nitrogen or argon atmosphere). The temperature of the annealing treatment is preferably 40 degrees Celsius or higher but 300 degrees Celsius or lower and more preferably 50 degrees Celsius or higher but 150 degrees Celsius or lower. By the annealing treatment, the stacked layers can permeate each other at the interface therebetween to have an increased effective contact area, which may be able to increase the short circuit current. The annealing treatment may be performed after formation of electrodes.

The solvent for mixing the P-type semiconductor material having the structure represented by the above General Formula (2) and the N-type semiconductor material is not particularly limited and may be appropriately selected depending on the intended purpose. Examples of the solvent include, but are not limited to, methanol, ethanol, butanol, toluene, xylene, o-chlorophenol, acetone, ethyl acetate, ethylene glycol, tetrahydrofuran, dichloromethane, chloroform, dichloroethane, chlorobenzene, dichlorobenzene, trichlorobenzene, chloronaphthalene, dimethylformamide, dimethyl sulfoxide, N-methylpyrrolidone, and γ-butyrolactone. These may be used alone or in combination. Of these, chlorobenzene, chloroform, and ortho-dichlorobenzene are particularly preferable.

The solution in which the P-type semiconductor material and the N-type semiconductor material are mixed together may further contain other components, if necessary.

The other components are not particularly limited and may be appropriately selected depending on the intended purpose. Examples of the other components include, but are not limited to, various additives such as diiodooctane, octanediol, and chloronaphthalene.

<Hole-Transporting Layer>

The hole-transporting layer can be provided to enhance hole collection efficiency.

Examples of a compound used for the hole-transporting layer include, but are not limited to, conductive polymers such as polyethylenedioxythiophene:polystyrene sulfonic acid (PEDOT:PSS), hole-transporting organic compounds such as aromatic amine derivatives, and inorganic compounds having hole transportability such as molybdenum oxide, tungsten oxide, vanadium oxide, nickel oxide, and copper(I) oxide. These may be used alone or in combination. Of these, molybdenum oxide, tungsten oxide, and vanadium oxide are particularly preferable.

The hole-transporting layer containing the above compound is formed by spin coating, the sol-gel method, or sputtering.

The average thickness of the hole-transporting layer is not particularly limited and may be appropriately selected depending on the intended purpose. The average thickness thereof is preferably 200 nm or less and more preferably 1 nm or more but 50 nm or less.

<Second Electrode>

The second electrode is an electrode layer on or above the hole-transporting layer.

The second electrode is preferably a metal electrode layer. The second electrode is preferably formed of a metal having a relatively low work function.

Examples of a material of the second electrode include, but are not limited to, gold, silver, aluminum, magnesium, and silver-magnesium alloys. A metal such as gold or aluminum can be stacked to adjust the band structure and hue.

The average thickness of the second electrode is not particularly limited and may be appropriately selected depending on the intended purpose. Form the viewpoint of photoelectric conversion efficiency, the average thickness thereof is preferably 20 nm or more but 300 nm or less and 50 nm or more but 200 nm or less.

The second electrode can be formed by any of, for example, various kinds of wet film formation, dry film formation such as vapor deposition or sputtering, and printing.

<Insulating Layer>

The insulating layer is a layer for preventing direct contact of the second electrode with the below-described sealing member. The insulating layer can effectively prevent the electrode from being peeled off by an adhesive sealing member upon folding.

A material of the insulating layer is not particularly limited and may be appropriately selected depending on the intended purpose. Examples of the material include, but are not limited to, metal oxides such as SiOx, SiOxNy, and Al₂O₃, and organic materials such as polyethylene, fluorine-based coating agents, and poly-para-xylylene. These may be used alone or in combination. Of these, a metal oxide is preferable. The average thickness of the insulating layer is preferably 1 nm or more but 10 micrometers or less.

A method for forming the insulating layer is not particularly limited and may be appropriately selected depending on the intended purpose. Examples of the method include, but are not limited to, vacuum vapor deposition, sputtering, reactive sputtering, molecular beam epitaxy (MBE), plasma CVD, laser CVD, thermal CVD, gas-source CVD, coating, printing, and transferring.

<Sealing Layer>

The sealing layer is a layer disposed to cover the exposed surface of each layer on or above the substrate, in order to block entry of moisture in the outside air and the atmosphere into the photoelectric conversion element.

Constituting members of the sealing layer are not particularly limited and may be appropriately selected depending on the intended purpose. The sealing layer is generally composed of, for example, an adhesive layer, a gas barrier layer, and a base, to have a film configuration for preventing transmission of moisture and oxygen.

An ability required for the sealing layer is generally represented by a water vapor transmission rate or an oxygen transmission rate. Depending on the kind of the photoelectric conversion element or the organic thin-film solar cell, the water vapor transmission rate is preferably lower than 1×10⁻² g/m²/day or the oxygen transmission rate is preferably lower than 1 cm³/m²/day/atm. These rates are preferably lower.

A specific member is preferably a base including a gas barrier layer.

When the sealing layer is located at a position opposite to the light-receiving surface, the sealing layer may or may not have light transmissivity.

The adhesive member for allowing the sealing layer to adhere to the insulating layer is not limited as long as the above properties can be ensured. The adhesive member may be a common adhesive member that is used for sealing of an organic electroluminescence element and an organic transistor. Specific examples of a material of the adhesive member include, but are not limited to, a pressure-sensitive adhesive resin, a thermosetting resin composition, a thermoplastic resin composition, and a photocurable resin composition. Of these, a pressure-sensitive adhesive resin is preferable because the organic thin-film solar cell does not need heating at a sealing step. More specific examples thereof include, but are not limited to, an ethylene-vinyl acetate copolymer resin composition, a styrene-isobutyrene resin composition, a hydrocarbon-based resin composition, an epoxy-based resin composition, a polyester-based resin composition, an acrylic-based resin composition, a urethane-based resin composition, and a silicone-based resin composition. By, for example, chemical modification of the main chain, branched chains, and terminals of these polymers, adjustment of molecular weights thereof, and use of additives, such properties as thermosetting, thermoplastic, and photocurable properties can be obtained.

<UV Cut Layer>

The UV cut layer is a layer disposed to cover the light incident surface of the substrate to suppress degradation of the photoelectric conversion element due to UV light.

Constituting members of the UV cut layer are not particularly limited and may be appropriately selected depending on the intended purpose. The UV cut layer is generally composed of, for example, an adhesive layer and a base to have a film configuration where at least one of the adhesive layer and the base absorbs UV light.

Depending on the intended purpose, two or more sealing layers and two or more UV cut layers may be provided, and other layers may be appropriately selected.

An ability required for the UV cut layer is generally represented by a light transmission rate. Depending on the kind of the photoelectric conversion element or the organic thin-film solar cell, the light transmission rate of light having a wavelength of 370 nm or shorter is preferably lower than 1%. More preferably, the light transmission rate of light having a wavelength of 410 nm or shorter is lower than 1%.

<Other Layers>

The other layers are not particularly limited and may be appropriately selected depending on the intended purpose. Examples thereof include, but are not limited to, a gas barrier layer, an insulating porous layer, a degradation preventing layer, and a protective layer.

<<Gas Barrier Layer>>

The gas barrier layer is provided for enhancing durability of the photoelectric conversion element.

The gas barrier layer is provided, for example, between the base and the first electrode and between the UV cut layer and the base.

The gas barrier layer means a layer having a water vapor transmission rate (g/(m²/day)) of 1×10⁻² g/(m²/day) or lower according to the JIS K7129 B method and an oxygen gas transmission rate (cm³/(m²·24 h·atm)) of 1 cm³/(m²·24 h·atm) or lower according to JIS K7126-2.

A method for forming the gas barrier layer is not particularly limited and may be appropriately selected depending on the intended purpose. Examples of the method include, but are not limited to, a method of attaching a film having a function as the gas barrier layer. A material of the gas barrier layer is not particularly limited and may be appropriately selected depending on the intended purpose. Examples of the material include, but are not limited to, SiO₂, SiNx, Al₂O₃, SiC, SiCN, SiOC, SiOAl, and siloxane-based materials. These may be used alone or in combination.

The photoelectric conversion element of the present disclosure configured in consideration of durability includes: the base including the gas barrier layer; the first electrode on the base; the electron-transporting layer on the first electrode; the photoelectric conversion layer on the electron-transporting layer; the hole-transporting layer on the photoelectric conversion layer; the second electrode on the hole-transporting layer; the insulating layer on the second electrode; and the sealing layer on the insulating layer, where the UV cut layer is provided on the light incident surface of the base.

In the photoelectric conversion element of the present disclosure, two or more photoelectric conversion layers may be stacked (as a tandem) via one or more intermediate electrodes, to form coupling in series or in parallel.

An attempt to enhance photoelectric conversion efficiency may be made by dividing incident light based on wavelengths using, for example, a dichroic mirror or a prism, and then allowing the light to enter an organic thin-film solar cell including two or more electricity-generating regions coupled in series or in parallel.

(Photoelectric Conversion Element Module)

The photoelectric conversion element module of the present disclosure includes the photoelectric conversion elements of the present disclosure which are coupled in series or in parallel.

The photoelectric conversion element module of the present disclosure can be applied to a power supply in combination with, for example, a circuit board configured to control generated electric current.

Examples of devices using a power supply include, but are not limited to, an electronic desk calculator and a watch. The power supply including the photoelectric conversion element module of the present disclosure can also be applied to, for example, a mobile phone, an electronic organizer, and electronic paper. The power supply including the photoelectric conversion element module of the present disclosure can also be used as, for example, an auxiliary power supply configured to prolong a continuous operation time of rechargeable electrical appliances or battery-type electrical appliances, or a power supply that can be used even in the nighttime by using it in combination with a secondary cell. The photoelectric conversion element module of the present disclosure can also be used in IoT devices or artificial satellites as self-supporting power supplies that require neither replacement of a cell nor power supply wirings.

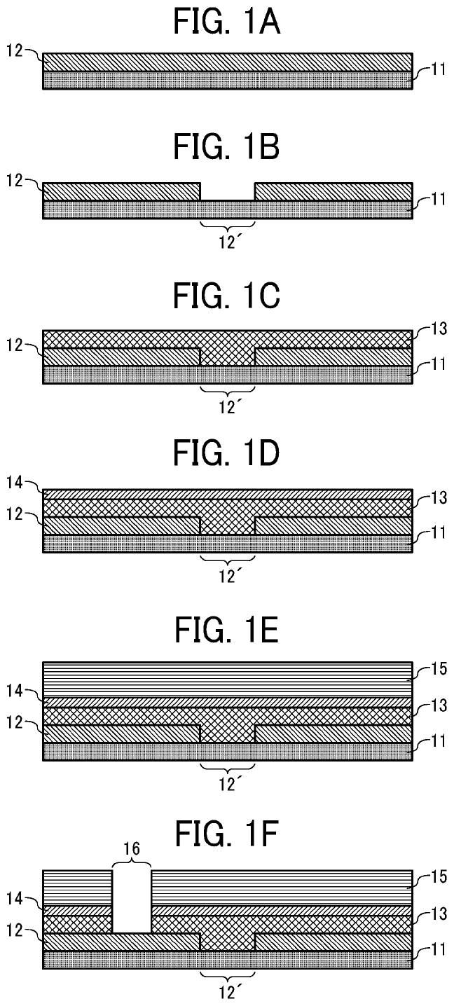

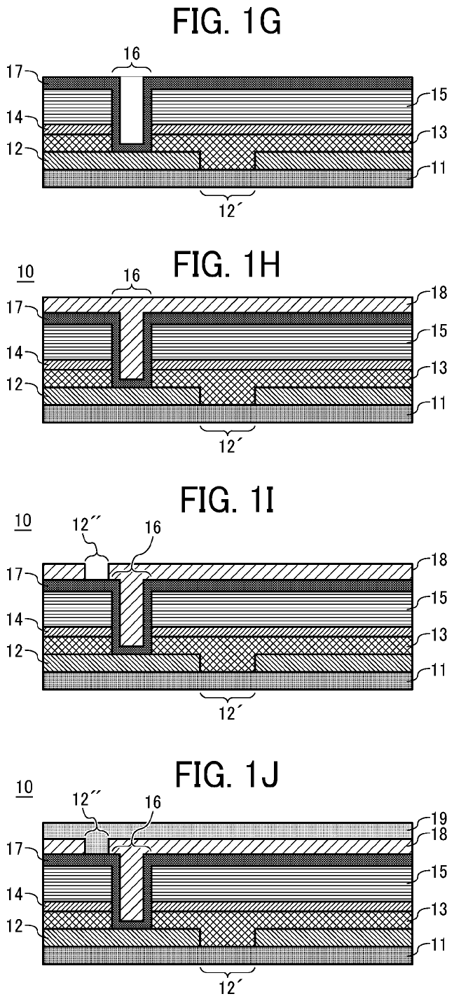

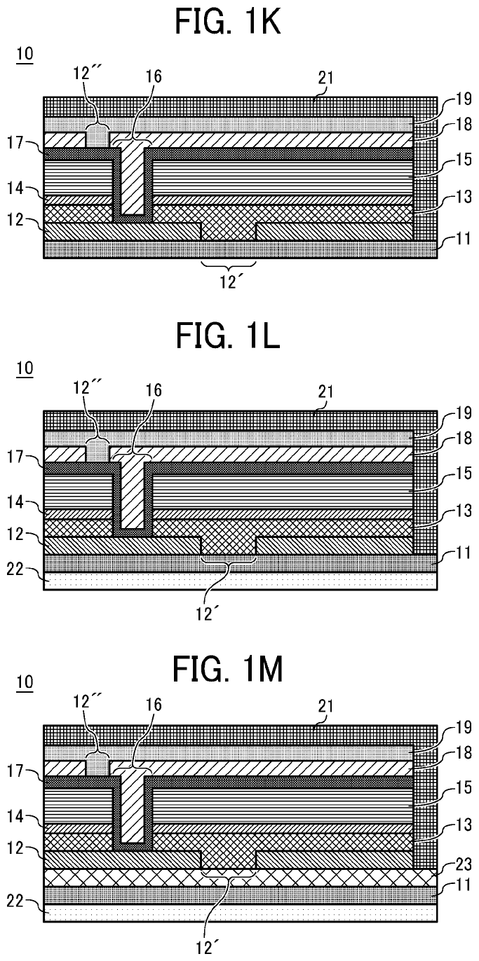

FIG. 1K is a cross-sectional view illustrating one example of the photoelectric conversion element module of the present disclosure. As illustrated in FIG. 1K, a photoelectric conversion element module 10 includes a base 11, a first electrode 12, a first electron-transporting layer 13, a second electron-transporting layer (intermediate layer) 14, a photoelectric conversion layer 15, a penetration portion 16, a hole-transporting layer 17, a second electrode 18, an insulating layer 19, and a sealing member 21.

In the photoelectric conversion element module 10 illustrated in FIG. 1K, the first electrode 12 is stacked on the base 11, the first electron-transporting layer 13 is stacked on the first electrode 12, the second electron-transporting layer (intermediate layer) 14 is stacked on the first electron-transporting layer 13, the photoelectric conversion layer 15 is stacked on the second electron-transporting layer (intermediate layer) 14, the hole-transporting layer 17 is stacked on the photoelectric conversion layer 15, the second electrode 18 is stacked on the hole-transporting layer 17, and the insulating layer 19 is stacked on the second electrode 18. The sealing member 21 allow the insulating layer 19 and the base 11 to adhere to each other so as to cover the stack on the base 11 from the above of the insulating layer 19.

As illustrated in FIG. 1K, the penetration portion 16 is a portion penetrating the electron-transporting layers 13 and 14 and the photoelectric conversion layer 15 in the cross-section of the photoelectric conversion element. The penetration portion 16 interior includes the hole-transporting layer 17 and the second electrode. The penetration portion interior means the interior of a space formed by the electron-transporting layers 13 and 14 and the photoelectric conversion layer 15.

In the penetration portion 16, as illustrated in FIG. 1K, the hole-transporting layer 17 is in contact with the second electrode, the photoelectric conversion layer 15, the electron-transporting layers 13 and 14, and the first electrode. In other words, the hole-transporting layer 17 is in contact with the second electrode disposed as an upper layer of the hole-transporting layer 17 and is in contact with the photoelectric conversion layer 15, the electron-transporting layers 13 and 14, and the first electrode which are disposed as under layers of the hole-transporting layer 17. With the simple structure described above, while the second electrode 18 is prevented from directly contacting the photoelectric conversion layer 15 and the electron-transporting layers 13 and 14, electrical coupling to the first electrode via the hole-transporting layer 17 can be formed.

FIG. 1L is a cross-sectional view illustrating one example of the photoelectric conversion element module of the present disclosure. As illustrated in FIG. 1L, the photoelectric conversion element module 10 includes a base 11, a first electrode 12, a first electron-transporting layer 13, a second electron-transporting layer (intermediate layer) 14, a photoelectric conversion layer 15, a penetration portion 16, a hole-transporting layer 17, a second electrode 18, an insulating layer 19, a sealing member 21, and a UV cut layer 22 on a surface opposite to the surface of the base 11 where the base 11 is in contact with the first electrode 12.

As illustrated in FIG. 1L, the UV cut layer 22 can suppress degradation due to UV light entering the photoelectric conversion element module.

FIG. 1M is a cross-sectional view illustrating one example of the photoelectric conversion element module of the present disclosure. As illustrated in FIG. 1M, the photoelectric conversion element module 10 includes a base 11, a first electrode 12, a first electron-transporting layer 13, a second electron-transporting layer (intermediate layer) 14, a photoelectric conversion layer 15, a penetration portion 16, a hole-transporting layer 17, a second electrode 18, an insulating layer 19, a sealing member 21, a gas barrier layer between the base 11 and the first electrode 12, and a UV cut layer 22.

As illustrated in FIG. 1M, the gas barrier layer can suppress degradation due to gas entering the photoelectric conversion element module and enhance durability.

(Method for Producing Photoelectric Conversion Element)

A method of the present disclosure for producing a photoelectric conversion element includes: an electron-transporting layer forming step of forming an electron-transporting layer on an exposed surface of a first electrode; a photoelectric conversion layer forming step of forming a photoelectric conversion layer on an exposed surface of the electron-transporting layer; a penetration portion forming step of forming a penetration portion penetrating the electron-transporting layer on the first electrode and the photoelectric conversion layer on the electron-transporting layer; a hole-transporting layer forming step of forming a hole-transporting layer on the exposed surface of the first electrode, the exposed surface of the electron-transporting layer, and an exposed surface of the photoelectric conversion layer; and a second electrode forming step of forming a second electrode on an exposed surface of the hole-transporting layer. If necessary, the method of the present disclosure further includes an insulating layer forming step, a sealing layer forming step, and other steps.

The exposed surface means a surface that is not covered with any substance other than the substance forming the electrode or the layer of interest.

Methods for forming each of the layers forming an organic thin-film solar cell including the photoelectric conversion element are roughly classified into dry methods, which are typified by, for example, vacuum vapor deposition and sputtering, and wet methods, which are typified by, for example, spin coating and dipping.

Stacked structures are: a normal structure where the first electrode, the hole-transporting layer on the first electrode, the photoelectric conversion layer on the hole-transporting layer, the electron-transporting layer on the photoelectric conversion layer, and the second electrode on the electron-transporting layer; and a reverse structure where the first electrode, the electron-transporting layer on the first electrode, the photoelectric conversion layer on the electron-transporting layer, the hole-transporting layer on the photoelectric conversion layer, and the second electrode on the hole-transporting layer.

As described above, production of an organic thin-film solar cell module requires division and coupling between the elements, which requires patterning of the electrodes and deletion of each layer.

Especially when stacking is performed by a film formation method without using masking or pattern printing, the part coupled in series is allowed to undergo deletion when the second electrode is formed, and formation of a through hole is required for coupling the second electrode to the first electrode of an adjacent element.

In the organic thin-film solar cell having the reverse structure, the hole-transporting layer and the second electrode are often continuously formed by the dry method in the same chamber. When deletion is required, the solar cell during production is taken out from the chamber after formation of the hole-transporting layer, followed by deletion. The resultant is placed again in a chamber to form the second electrode, which may lead to inefficiency in the production process.

The present inventors have found in a method for producing a photoelectric conversion element that when desired regions of an electron-transporting layer and a photoelectric conversion layer are deleted (deletion) before formation of a hole-transporting layer to form a penetration portion, followed by forming a hole-transporting layer and a second electrode, photoelectric conversion characteristics comparable to those of the existing photoelectric conversion elements can be maintained while simplifying a production process and the structure of a photoelectric conversion element to be produced.

The method of the present disclosure for producing a photoelectric conversion element can be suitably used for producing the photoelectric conversion element of the present disclosure.

In the method of the present disclosure for producing a photoelectric conversion element, the first electrode is formed on the substrate.

A method for forming the first electrode is not particularly limited and may be appropriately selected depending on the intended purpose. The formation method described for the photoelectric conversion element of the present disclosure can be used.

<Electron-Transporting Layer Forming Step>

The electron-transporting layer forming step is a step of forming an electron-transporting layer on an exposed surface of the first electrode.

A method for forming the electron-transporting layer is not particularly limited and may be appropriately selected depending on the intended purpose. The formation method described for the photoelectric conversion element of the present disclosure can be used.

<Photoelectric Conversion Layer Forming Step>

The photoelectric conversion layer forming step is a step of forming a photoelectric conversion layer on an exposed surface of the electron-transporting layer.

A method for forming the photoelectric conversion layer is not particularly limited and may be appropriately selected depending on the intended purpose. The formation method described for the photoelectric conversion element of the present disclosure can be used.

<Penetration Portion Forming Step>

The penetration portion forming step is a step of forming a penetration portion penetrating the electron-transporting layer on the first electrode and the photoelectric conversion layer on the electron-transporting layer.

A method for forming the penetration portion is not particularly limited and may be appropriately selected depending on the intended purpose as long as the method allows for penetration through the electron-transporting layer and the photoelectric conversion layer. Examples of the method include, but are not limited to, laser deletion and mechanical scribing.

The shape, structure, and size of the penetration portion are not particularly limited and may be appropriately selected depending on the intended purpose as long as the penetration portion can electrically couple the first electrode and the second electrode to each other.

When two or more photoelectric conversion elements are produced on the same substrate and coupled in series to form a module structure, the penetration portion is not particularly limited and may be appropriately selected depending on the intended purpose as long as part of the layer on the first electrode of photoelectric conversion element is removed and the second electrode can be electrically coupled to the first electrode.

The shape of the penetration portion is not particularly limited and may be appropriately selected depending on the intended purpose. In a plan view of the photoelectric conversion element, the shape of the penetration portion is, for example, a line shape or a circular shape. In a cross-sectional view of the photoelectric conversion element, the shape of the penetration portion is, for example, a rectangular shape or a square shape.

<Hole-Transporting Layer Forming Step>

The hole-transporting layer forming step is a step of forming a hole-transporting layer on the exposed surface of the first electrode, the exposed surface of the electron-transporting layer, and an exposed surface of the photoelectric conversion layer.

A method for forming the hole-transporting layer is not particularly limited and may be appropriately selected depending on the intended purpose. The formation method described for the photoelectric conversion element of the present disclosure can be used.

<Second Electrode Forming Step>

The second electrode forming step is a step of forming a second electrode on an exposed surface of the hole-transporting layer.

A method for forming the second electrode is not particularly limited and may be appropriately selected depending on the intended purpose. The formation method described for the photoelectric conversion element of the present disclosure can be used.

<Insulating Layer Forming Step>

The insulating layer forming step is a step of forming an insulating layer on an exposed surface of the second electrode.

A method for forming the insulating layer is not particularly limited and may be appropriately selected depending on the intended purpose. The formation method described for the photoelectric conversion element of the present disclosure can be used.

<Sealing Layer Forming Step>

The sealing layer forming step is a step of forming a sealing layer by providing a sealing member so as to cover the exposed surfaces of the layers on or above the substrate to avoid contact of the layers with the outside air.

A method for forming the sealing layer is not particularly limited and may be appropriately selected depending on the intended purpose. The formation method described for the photoelectric conversion element of the present disclosure can be used.

<UV Cut Layer Forming Step>

The UV cut layer forming step is a step of providing a UV cut layer forming material so as to cover a light incident surface of the substrate, in order to suppress degradation of the photoelectric conversion element due to UV light.

A method for forming the UV cut layer is not particularly limited and may be appropriately selected depending on the intended purpose. The formation method described for the photoelectric conversion element of the present disclosure can be used.

<Other Steps>

The other steps are not particularly limited and may be appropriately selected depending on the intended purpose. Examples thereof include, but are not limited to, a gas barrier layer forming step, an insulating porous layer forming step, a degradation preventing layer forming step, and a protective layer forming step.

<Gas Barrier Layer Forming Step>

The gas barrier layer forming step is a step of forming a layer that is provided to avoid exposure of the photoelectric conversion element to the outside air, in order to enhance durability of the photoelectric conversion element.

A method for forming the gas barrier layer is not particularly limited and may be appropriately selected depending on the intended purpose. The formation method described for the photoelectric conversion element of the present disclosure can be used.

Referring now to the drawings, the method of the present disclosure for producing a photoelectric conversion element (module) will be described in detail.

FIG. 1A to FIG. 1M are views illustrating one example of the method of the present disclosure for producing a photoelectric conversion element (module).

As illustrated in FIG. 1A, first, a first electrode 12 is formed on a substrate 11. When two or more photoelectric conversion elements are formed on one substrate 11, as illustrated in FIG. 1B, a separation part 12′ is formed by deleting part of the first electrode. Next, as illustrated in FIG. 1C and FIG. 1D, a first electron-transporting layer 13 is formed on the substrate 11 and the first electrode 12 and the second electron-transporting layer (intermediate layer) 14 was formed on the first electron-transporting layer 13. Next, as illustrated in FIG. 1E, a photoelectric conversion layer 15 is formed on the electron-transporting layer 14. After the formation of the photoelectric conversion layer 15, as illustrated in FIG. 1F, predetermined regions of the electron-transporting layers 13 and 14 and the photoelectric conversion layer 15 on or above the first electrode are deleted to form a penetration portion 16. After the formation of the penetration portion 16, as illustrated in FIG. 1G and FIG. 1H, a hole-transporting layer 17 and a second electrode 18 are formed. When two or more photoelectric conversion elements are formed on one substrate 11, as illustrated in FIG. 1I, a separation part 12″ is formed in the second electrode 18 to separate one photoelectric conversion element.

In the method of the present disclosure for producing a photoelectric conversion element, as illustrated in FIG. 1J and FIG. 1K, after an insulating layer 19 is formed on the second electrode 18, a sealing member may be disposed so as to cover the photoelectric conversion element 10 on the substrate. In the method of the present disclosure for producing a photoelectric conversion element, as illustrated in FIG. 1L, a UV cut layer 22 may be provided on the exposed surface of the substrate 11. As illustrated in FIG. 1M, a gas barrier layer 23 may be provide between the first electrode 12 and the substrate 11.

(Electronic Device)

In a first aspect, an electronic device of the present disclosure includes: at least one of the photoelectric conversion element and the photoelectric conversion element module of the present disclosure; and a device configured to be driven by electric power generated through photoelectric conversion of the at least one of the photoelectric conversion element and the photoelectric conversion element module. If necessary, the electronic device of the present disclosure further includes other devices.

In a second aspect, an electronic device of the present disclosure includes: at least one of the photoelectric conversion element and the photoelectric conversion element module of the present disclosure; an electricity storage cell configured to store electric power generated through photoelectric conversion of the at least one of the photoelectric conversion element and the photoelectric conversion element module; and a device configured to be driven by at least one of: the electric power generated through photoelectric conversion of the at least one of the photoelectric conversion element and the photoelectric conversion element module; and the electric power stored in the electricity storage cell. If necessary, the electronic device of the present disclosure further includes other devices.

(Power Supply Module)

A power supply module of the present disclosure includes: at least one of the photoelectric conversion element of the present disclosure and the photoelectric conversion element module of the present disclosure; and a power supply integrated circuit (IC). If necessary, the power supply module of the present disclosure further includes other devices

A specific embodiment of the electronic device including the photoelectric conversion element of the present disclosure and the photoelectric conversion element module of the present disclosure and a device configured to be driven by electric power obtained through electricity generation of these element and module will be described.

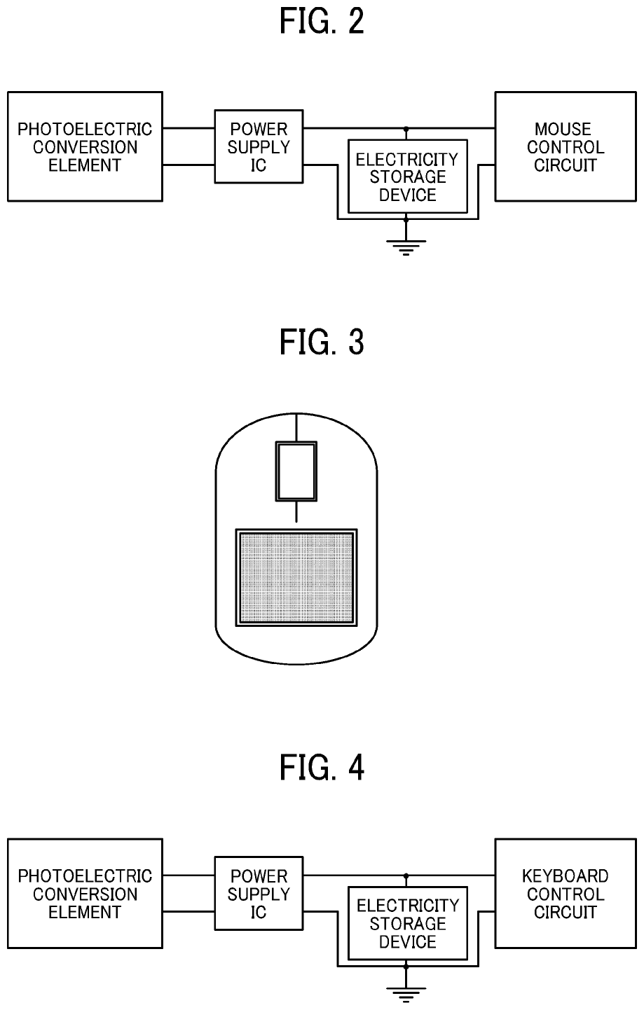

FIG. 2 is a block diagram of a mouse for a personal computer as one example of an electronic device of the present disclosure.

As illustrated in FIG. 2, a photoelectric conversion element and a photoelectric conversion element module, a power supply IC, and an electricity storage device are combined and the supplied electric power is allowed to pass to a power supply of a control circuit of a mouse. The electricity storage device is charged when the mouse is not used, and the mouse can be driven by the electric power stored. A mouse that requires neither wiring nor replacement of a cell can be obtained. Since a cell is not required, the weight of the mouse can be reduced, which is advantageous.

FIG. 3 is a schematic external view illustrating one example of the mouse illustrated in FIG. 2.

As illustrated in FIG. 3, a photoelectric conversion element, a power supply IC, and an electricity storage device are mounted inside a mouse. The upper part of the photoelectric conversion element is covered with a transparent casing so that the photoelectric conversion element receives light. The whole casing of the mouse can also be formed with a transparent resin. The arrangement of the photoelectric conversion element is not limited to the above-described arrangement. For example, the photoelectric conversion element may be arranged at a position where the photoelectric conversion element receives light even when the mouse is covered with a hand. Such an arrangement may be preferable.

Another embodiment of the electronic device including the photoelectric conversion element of the present disclosure and the photoelectric conversion element module of the present disclosure and a device configured to be driven by electric power obtained through electricity generation of these element and module will be described.

FIG. 4 is a block diagram of a keyboard for a personal computer as one example of an electronic device of the present disclosure.

As illustrated in FIG. 4, a photoelectric conversion element, a power supply IC, and an electricity storage device are combined, and the supplied electric power is allowed to pass to a power supply of a control circuit of a keyboard. The electricity storage device is charged when the keyboard is not used, and the keyboard can be driven by the electric power stored. A keyboard that requires neither wiring nor replacement of a cell can be obtained. Since a cell is not required, the weight of the keyboard can be reduced, which is advantageous.

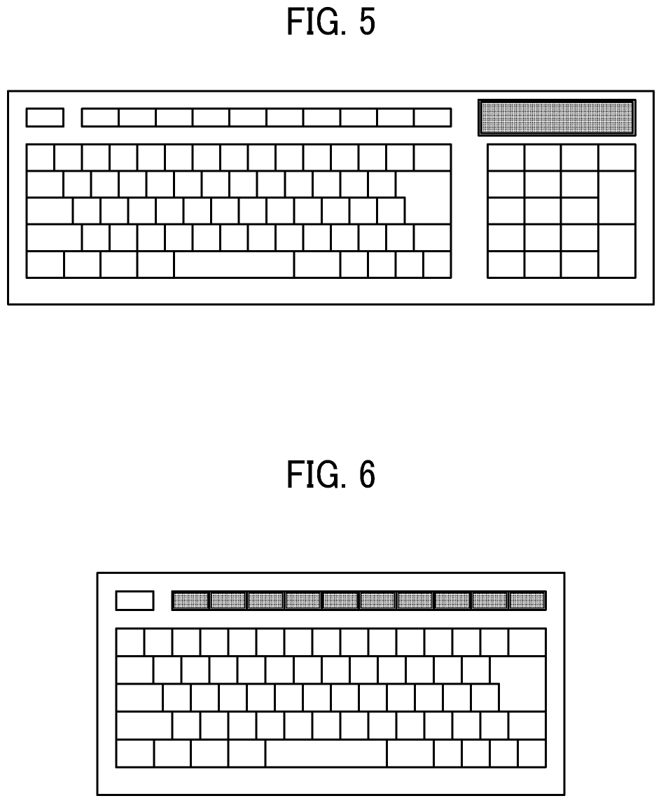

FIG. 5 is a schematic external view illustrating one example of the keyboard illustrated in FIG. 4.

As illustrated in FIG. 5, a photoelectric conversion element, a power supply IC, and an electricity storage device are mounted inside the keyboard. The upper part of the photoelectric conversion element is covered with a transparent casing so that the photoelectric conversion element receives light. The whole casing of the keyboard can also be formed with a transparent resin. The arrangement of the photoelectric conversion element is not limited to the above-described arrangement.

In the case of a small keyboard in which a space for receiving the photoelectric conversion element is small, as illustrated in FIG. 6, a small photoelectric conversion element may be embedded in some keys, which is advantageous.

Next, another embodiment of an electronic device including the photoelectric conversion element of the present disclosure and the photoelectric conversion element module of the present disclosure and a device configured to be driven by electric power obtained through power generation of these element and module will be described.

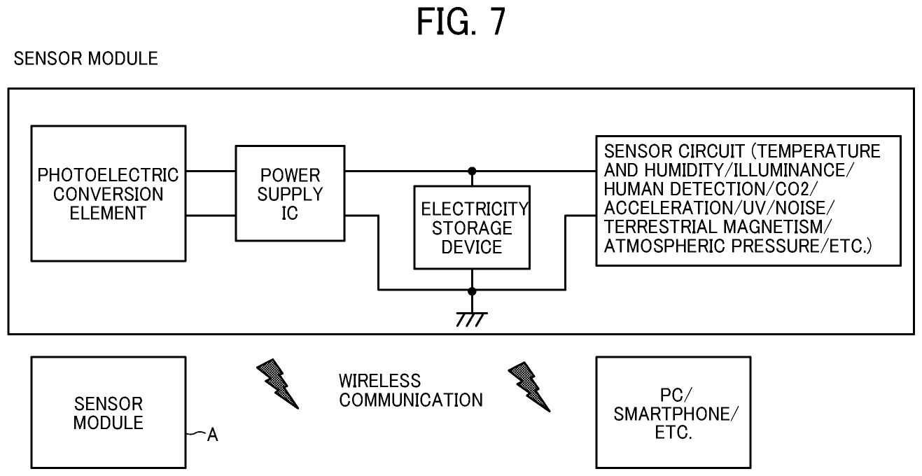

FIG. 7 is a block diagram of a sensor as one example of an electronic device of the present disclosure.

As illustrated in FIG. 7, a photoelectric conversion element, a power supply IC, and an electricity storage device are combined, and the supplied electric power is allowed to pass to a power supply of a sensor circuit. A sensor module can be configured without coupling to an external power supply nor replacement of a cell. A sensing target is, for example, temperature and humidity, illuminance, human detection, CO₂, acceleration, UV, noise, terrestrial magnetism, and atmospheric pressure. The electronic device can be applied to various sensors, which is advantageous. As illustrated in “A” in FIG. 7, the sensor module is configured to sense a measurement target on a regular basis and to transmit the read data to, for example, a personal computer (PC) or a smartphone through wireless communication.

It is expected that use of sensors will be significantly increased in response to realization of the internet of things (IoT) society. Replacing cells of numerous sensors one by one takes a lot of effort and is not realistic. Sensors installed at positions where cell replacement is not easy, such as a ceiling and a wall, make workability low. The fact that electricity can be supplied by the photoelectric conversion element is significantly advantageous. The photoelectric conversion element of the present disclosure has such advantages that a high output can be obtained even with light of a low illuminance, and a high degree of freedom in installation can be achieved because dependency of the output on light incident angle is small.

Next, another embodiment of an electronic device including the photoelectric conversion element of the present disclosure and the photoelectric conversion module of the present disclosure and a device configured to be driven by electric power obtained through power generation of these element and module will be described.

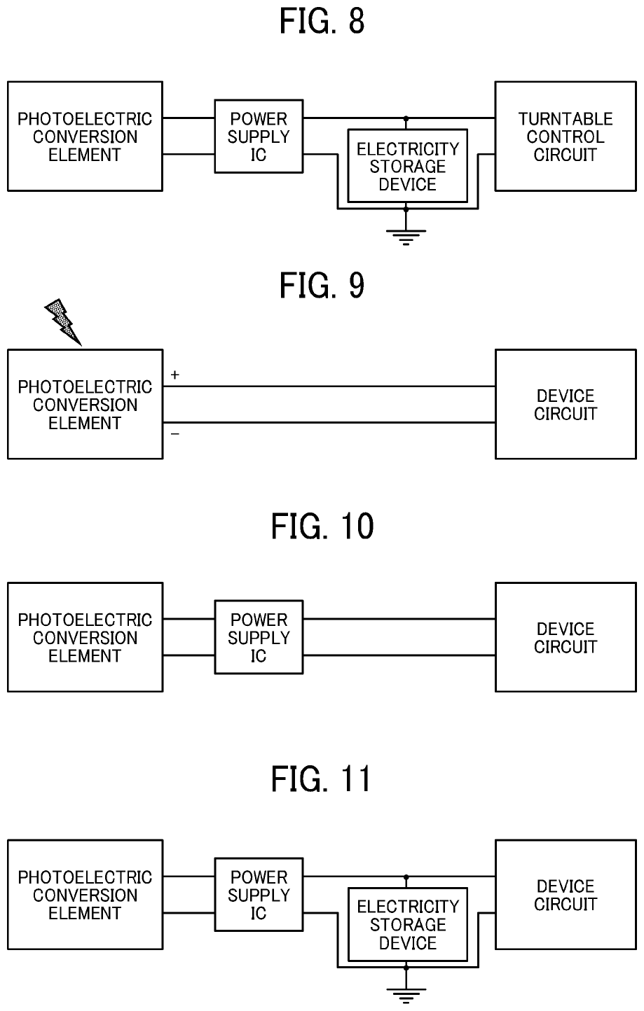

FIG. 8 is a block diagram of a turntable as one example of the electronic device of the present disclosure.

As illustrated in FIG. 8, a photoelectric conversion element, a power supply IC, and an electricity storage device are combined, and the supplied electric power is allowed to pass to a power supply of a turntable control circuit. A turntable can be configured without coupling to an external power supply nor replacement of a cell.

The turntable is used in, for example, a display case in which products are displayed. Wirings of a power supply degrade appearance of the display. Displayed products need removing when replacing a cell, which takes a lot of effort. Use of the photoelectric conversion element of the present disclosure can overcome such disadvantages, which is advantageous.

<Use>

The photoelectric conversion element and the photoelectric conversion module of the present disclosure can function as a self-sustaining power supply and drive a device using electric power generated through photoelectric conversion. Since the photoelectric conversion element and the photoelectric conversion module of the present disclosure can generate electricity by irradiation with light, it is not necessary to couple an electronic device to a power supply or replace a cell. The electronic device can be driven in a place where there is no power supply facility. The electronic device can be worn or carried. The electronic device can be driven without replacement of a cell even in a place where cell replacement is not easy. When a dry cell is used, the electronic device becomes heavier by the weight of the dry cell, or the electronic device becomes larger by the size of the dry cell. There may be a problem in installing the electronic device on a wall or ceiling, or transporting the electronic device. However, since the photoelectric conversion element of the present disclosure and the photoelectric conversion element module of the present disclosure are light and thin, they can be highly freely installed and be worn and carried, which is advantageous.

The photoelectric conversion element of the present disclosure and the photoelectric conversion element module of the present disclosure can be used as a self-sustaining power supply, and can be combined with various electronic devices. For example, these element and module can be used in combination with a display device, such as an electronic desk calculator, a watch, a mobile phone, an electronic organizer, or electronic paper, an accessory device of a personal computer, such as a mouse or a keyboard, various sensor devices, such as a temperature and humidity sensor and a human detection sensor, a transmitter, such as a beacon or a global positioning system (GPS), or numerous electronic devices, such as an auxiliary lighting and a remote controller.

The photoelectric conversion element of the present disclosure and the photoelectric conversion element module of the present disclosure can generate electricity even with light of a low illuminance.

The low illuminance is an illuminance of from about 20 lx through about 1,000 lx as seen in an indoor environment irradiated with, for example, a lighting. The low illuminance is much lower than direct sunlight (about 100,000 lx). The photoelectric conversion element of the present disclosure and the photoelectric conversion element module of the present disclosure have a wide variety of applications because they can generate electricity even in indoor environments and in further darker shaded areas. The photoelectric conversion element of the present disclosure and the photoelectric conversion element module of the present disclosure are highly safe because liquid leakage found in the case of a dry cell does not occur, and accidental swallowing found in the case of a button cell does not occur. The photoelectric conversion element of the present disclosure and the photoelectric conversion element module of the present disclosure can be used as an auxiliary power supply for the purpose of prolonging a continuous operation time of a charge-type or dry cell-type electrical appliance. When the photoelectric conversion element of the present disclosure and the photoelectric conversion element module of the present disclosure are combined with a device configured to be driven by electric power generated through photoelectric conversion of these element and module, it is possible to obtain an electronic device that is light and easy to use, has a high degree of freedom in installation, does not require replacement of a cell, is excellent in safety, and is effective in reducing environmental load.

FIG. 9 illustrates a basic configurational diagram of an electronic device obtained by combining at least one of the photoelectric conversion element of the present disclosure and the photoelectric conversion module of the present disclosure with a device configured to be driven by electric power generated through photoelectric conversion of the photoelectric conversion module. The electronic device can generate electricity when the photoelectric conversion element is irradiated with light, and can take out electric power. A circuit of the device can be driven by the generated electric power.

Since the output of the photoelectric conversion element varies depending on the illuminance of the surroundings, the electronic device illustrated in FIG. 9 cannot sometimes be stably driven. In this case, as illustrated in FIG. 10, a power supply IC for a photoelectric conversion element can be incorporated between the photoelectric conversion element and the circuit of the device to supply stable voltage to a side of the circuit, which is advantageous. The photoelectric conversion element can generate electricity as long as the photoelectric conversion element is irradiated with light having a sufficient illuminance. However, when an illuminance is not enough to generate electricity, desired electric power cannot be obtained, which is a disadvantage of the photoelectric conversion element. In this case, as presented in FIG. 11, when an electricity storage device such as a capacitor is provided between a power supply IC and a device circuit, excess electric power from the photoelectric conversion element can be stored in the electricity storage device. Even when the illuminance is too low or light is not applied to the photoelectric conversion element, the electric power stored in the electricity storage device can be supplied to a device circuit to allow for stable operation.

The electronic device obtained by combining at least one of the photoelectric conversion element of the present disclosure and the photoelectric conversion module of the present disclosure with the device circuit can be driven even in an environment without a power supply, does not require replacement of a cell, and can be stably driven, when combined with a power supply IC or an electricity storage device. It is possible to make the most of advantages of the photoelectric conversion element.

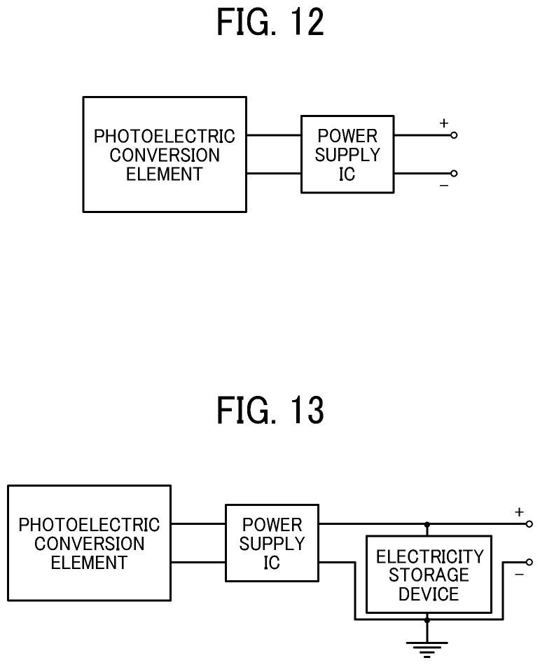

At least one of the photoelectric conversion element of the present disclosure and the photoelectric conversion module of the present disclosure can also be used as a power supply module, which is useful. As illustrated in FIG. 12, for example, when the at least one of the photoelectric conversion element of the present disclosure and the photoelectric conversion module of the present disclosure is coupled to a power supply IC for a photoelectric conversion element, it is possible to configure a direct current power supply module, which is capable of supplying electric power generated through photoelectric conversion of the photoelectric conversion element to the power supply IC at a predetermined voltage level.

As illustrated in FIG. 13, when an electricity storage device is added to a power supply IC, electric power generated by the photoelectric conversion element can be stored in the electricity storage device. It is possible to configure a power supply module capable of supplying electric power even when the illuminance is too low or light is not applied to the photoelectric conversion element.

The power supply modules of the present disclosure illustrated in FIG. 12 and FIG. 13 can be used as a power supply module without replacement of a cell as like in traditional primary cells.

### EXAMPLES

The present disclosure will be described below in more detail by way of Examples. However, the present disclosure should not be construed as being limited to the Examples.

### Example 1

<Production of Photoelectric Conversion Element Module>

—Base with First Electrode—

First, a polyethylene terephthalate (PET) substrate (50 mm×50 mm) with a gas barrier film having a patterned indium-doped tin oxide (ITO) was purchased from GEOMATEC Co., Ltd.

—Formation of Electron-Transporting Layer—

Next, a liquid of zinc oxide nanoparticles (obtained from Aldrich Co., average particle diameter: 12 nm) was spin-coated at 3,000 rpm on the ITO gas barrier PET film (15 Ω/sq.), followed by drying at 100 degrees Celsius for 10 minutes, to form an electron-transporting layer having an average thickness of 30 nm.

—Formation of Intermediate Layer—

Next, an intermediate layer was formed in the following manner. Specifically, dimethylaminobenzoic acid (obtained from Tokyo Chemical Industry Co., Ltd.) was dissolved in ethanol to prepare a 1 mg/ml solution. The solution was spin-coated at 3,000 rpm on the electron-transporting layer to form an intermediate layer of less than 10 nm.

—Formation of Photoelectric Conversion Layer—

15 mg of Exemplary Compound 1 presented below (number average molecular weight (Mn): 1,554, highest occupied molecular orbital (HOMO) level: 5.13 eV) and 10 mg of Exemplary Compound 3 presented below were dissolved in 1 mL of chloroform to prepare photoelectric conversion layer coating liquid A.

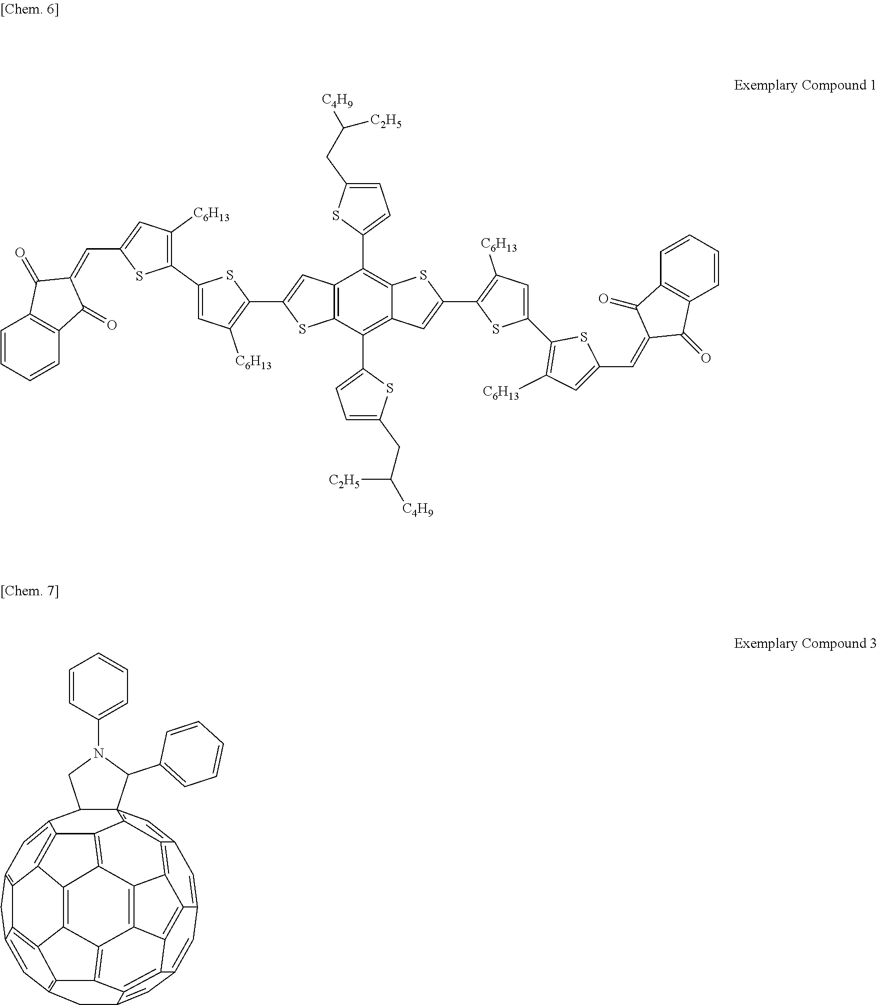

Next, the photoelectric conversion layer coating liquid A was spin-coated at 600 rpm on the intermediate layer to form a photoelectric conversion layer having an average thickness of 200 nm.

—Formation of Hole-Transporting Layer and Formation of Second Electrode—

Next, as the part coupled in series between the photoelectric conversion elements, laser deletion was used so that the distance between the centers of the parts coupled in series would be 5.6 mm in a plan view of the photoelectric conversion element, to form a penetration portion (deletion). The penetration portion was formed to have a rectangular shape and a width of 0.3 mm. A hole-transporting layer of molybdenum oxide (obtained from Kojundo Chemical Lab. Co., Ltd.) was formed on the photoelectric conversion layer to have an average thickness of 50 nm. Then, a second electrode of silver was formed to have an average thickness of 100 nm. The hole-transporting layer and the second electrode were formed through vacuum vapor deposition.

—Evaluation of Relative Time of Production Process—

After the formation of the photoelectric conversion layer, a process time from the deletion of the part coupled in series until the formation of the hole-transporting layer and the formation of the second electrode was measured. Results are presented in Table 1. A relative time of the production process is expressed as a relative time when the time of the production process in Example 3 was regarded as 1.

—Evaluation of Characteristics of Solar Cell Over Time—

Each of the elements of the produced module was measured for current-voltage characteristics under irradiation with white LED (0.07 mW/cm², illuminance: 200 lx). In current-voltage measurement of each element, the measurement was performed via the first electrode of the element of interest and the first electrode of a separated element to which the second electrode of the element of interest was coupled in series. From the obtained current-voltage curve, the photoelectric conversion efficiency was calculated. A white LED lighting used was a bulb-shaped LED lamp (LDA11N-G/100 W, obtained from TOSHIBA LIGHTHING & TECHNOLOGY CORPORATION). An evaluation device (source meter) used for the measurement was KETSIGHT B2902A. The output of the LED light source was measured with spectra light color meter C-7000 obtained from SEKONIC CORPORATION. Results are presented in Table 1.

The produced photoelectric conversion element module was left to stand at normal temperature and normal humidity for 500 hours under white LED irradiation (illuminance: 10,000 lx). Then, according to the above-described evaluation of characteristics of solar cell, the characteristics of the solar cell were evaluated to calculate a photoelectric conversion rate relative to 100% of the initial photoelectric conversion rate. Results are presented in Table 1.

### Example 2

<Production of Photoelectric Conversion Element Module>

In the same manner as in Example 1 except that the thickness of the hole-transporting layer was changed to an average thickness of 100 nm, a photoelectric conversion element module was produced and evaluated. Results are presented in Table 1.

### Example 3

<Production of Photoelectric Conversion Element Module>

In the same manner as in Example 1 except that the thickness of the hole-transporting layer was changed to an average thickness of 200 nm, a photoelectric conversion element module was produced and evaluated. Results are presented in Table 1.

### Example 4

<Production of Photoelectric Conversion Element Module>

In the same manner as in Example 1 except that the thickness of the hole-transporting layer was changed to an average thickness of 300 nm, a photoelectric conversion element module was produced and evaluated. Results are presented in Table 1.

### Example 5

<Production of Photoelectric Conversion Element Module>

In the same manner as in Example 1 except that the thickness of the hole-transporting layer was changed to an average thickness of 10 nm, a photoelectric conversion element module was produced and evaluated. Results are presented in Table 1.

### Example 6

<Production of Photoelectric Conversion Element Module>

In the same manner as in Example 1 except that the thickness of the hole-transporting layer was changed to an average thickness of 30 nm, a photoelectric conversion element module was produced and evaluated. Results are presented in Table 1.

### Example 7

<Production of Photoelectric Conversion Element Module>

In the same manner as in Example 1 except that the photoelectric conversion layer coating liquid A was changed to the following photoelectric conversion layer coating liquid B, a photoelectric conversion element module was produced and evaluated. Results are presented in Table 1.

—Formation of Photoelectric Conversion Layer—

15 mg of Exemplary Compound 2 presented below (number average molecular weight (Mn): 1,463, highest occupied molecular orbital (HOMO) level: 5.27 eV) and 10 mg of Exemplary Compound 3 presented below were dissolved in 1 mL of chloroform to prepare photoelectric conversion layer coating liquid B.

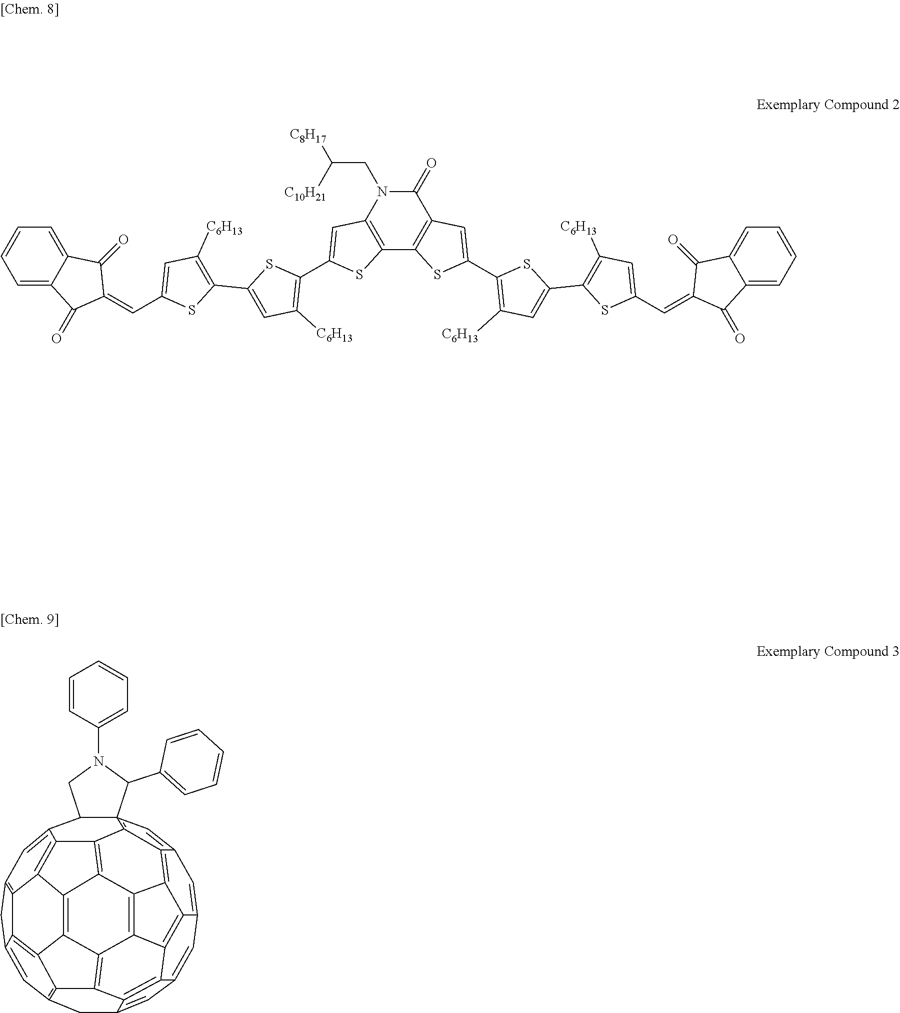

Next, the photoelectric conversion layer coating liquid B was spin-coated at 600 rpm on the intermediate layer to form a photoelectric conversion layer having an average thickness of 200 nm.

### Example 8

<Production of Photoelectric Conversion Element Module>

In the same manner as in Example 1 except that the photoelectric conversion layer coating liquid A was changed to the following photoelectric conversion layer coating liquid C, a photoelectric conversion element module was produced and evaluated. Results are presented in Table 1.

—Formation of Photoelectric Conversion Layer—

15 mg of Exemplary Compound 4 presented below (number average molecular weight (Mn): 2,029, highest occupied molecular orbital (HOMO) level: 5.50 eV) and 10 mg of Exemplary Compound 3 presented below were dissolved in 1 mL of chloroform to prepare photoelectric conversion layer coating liquid C.

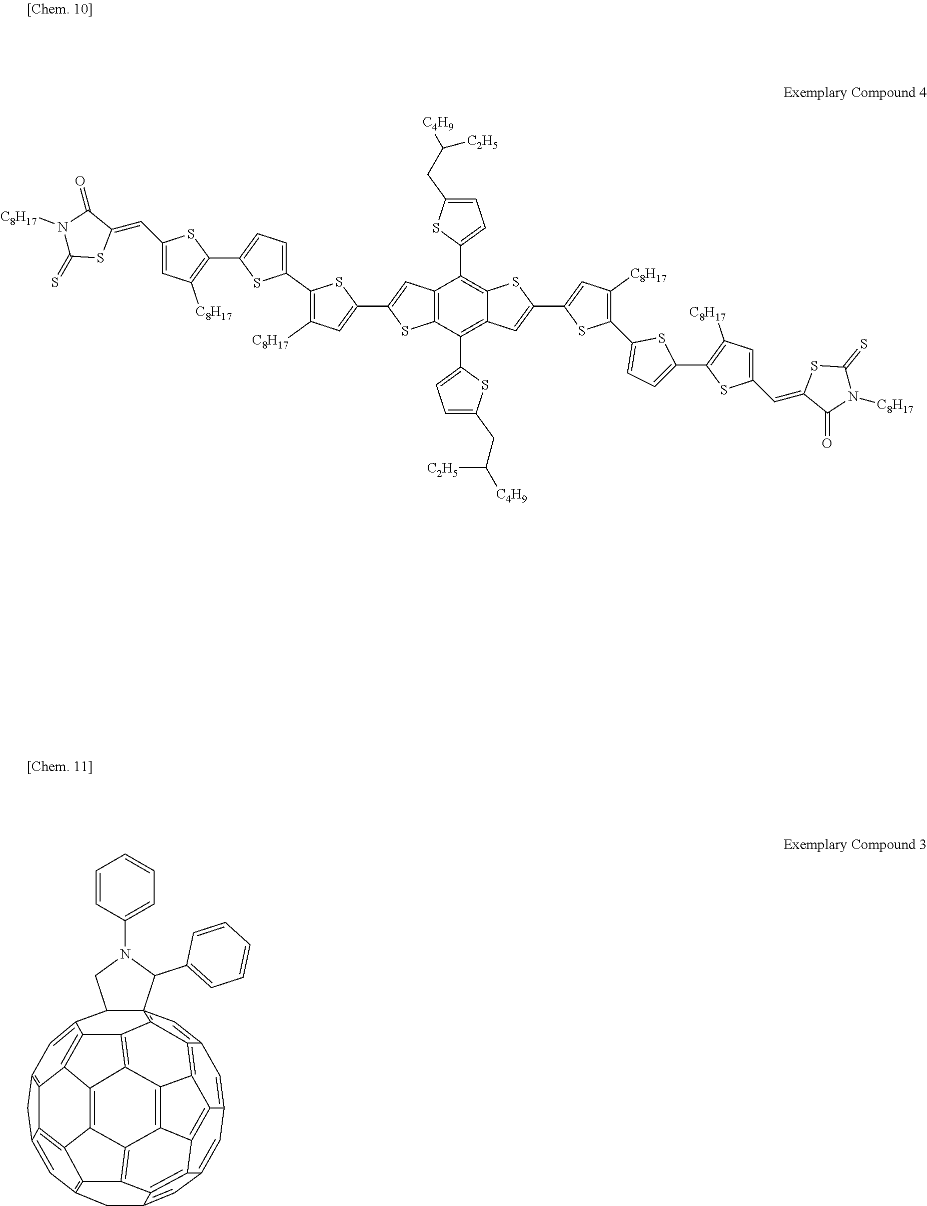

Next, the photoelectric conversion layer coating liquid C was spin-coated at 600 rpm on the intermediate layer to form a photoelectric conversion layer having an average thickness of 200 nm.

### Example 9

<Production of Photoelectric Conversion Element Module>

In the same manner as in Example 1 except that the photoelectric conversion layer coating liquid A was changed to the following photoelectric conversion layer coating liquid D, a photoelectric conversion element module was produced and evaluated. Results are presented in Table 1.

—Formation of Photoelectric Conversion Layer—

15 mg of Exemplary Compound 1 presented below (number average molecular weight (Mn): 1,554) and 10 mg of fullerene derivative PC61BM (E100H, obtained from Frontier Carbon Corporation) were dissolved in 1 mL of chloroform to prepare photoelectric conversion layer coating liquid D.

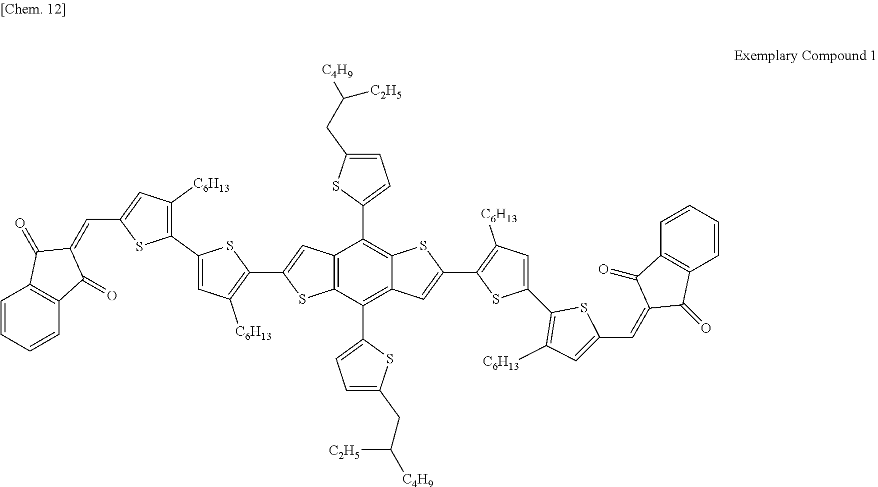

Next, the photoelectric conversion layer coating liquid D was spin-coated at 600 rpm on the intermediate layer to form a photoelectric conversion layer having an average thickness of 200 nm.

### Example 10

<Production of Photoelectric Conversion Element Module>

In the same manner as in Example 1 except that the photoelectric conversion layer coating liquid A was changed to the following photoelectric conversion layer coating liquid E, a photoelectric conversion element module was produced and evaluated. Results are presented in Table 1.

—Formation of Photoelectric Conversion Layer—

15 mg of Exemplary Compound 5 presented below (number average molecular weight (Mn): 1,806, highest occupied molecular orbital (HOMO) level: 5.20 eV) and 10 mg of Exemplary Compound 3 presented below were dissolved in 1 mL of chloroform to prepare photoelectric conversion layer coating liquid E.

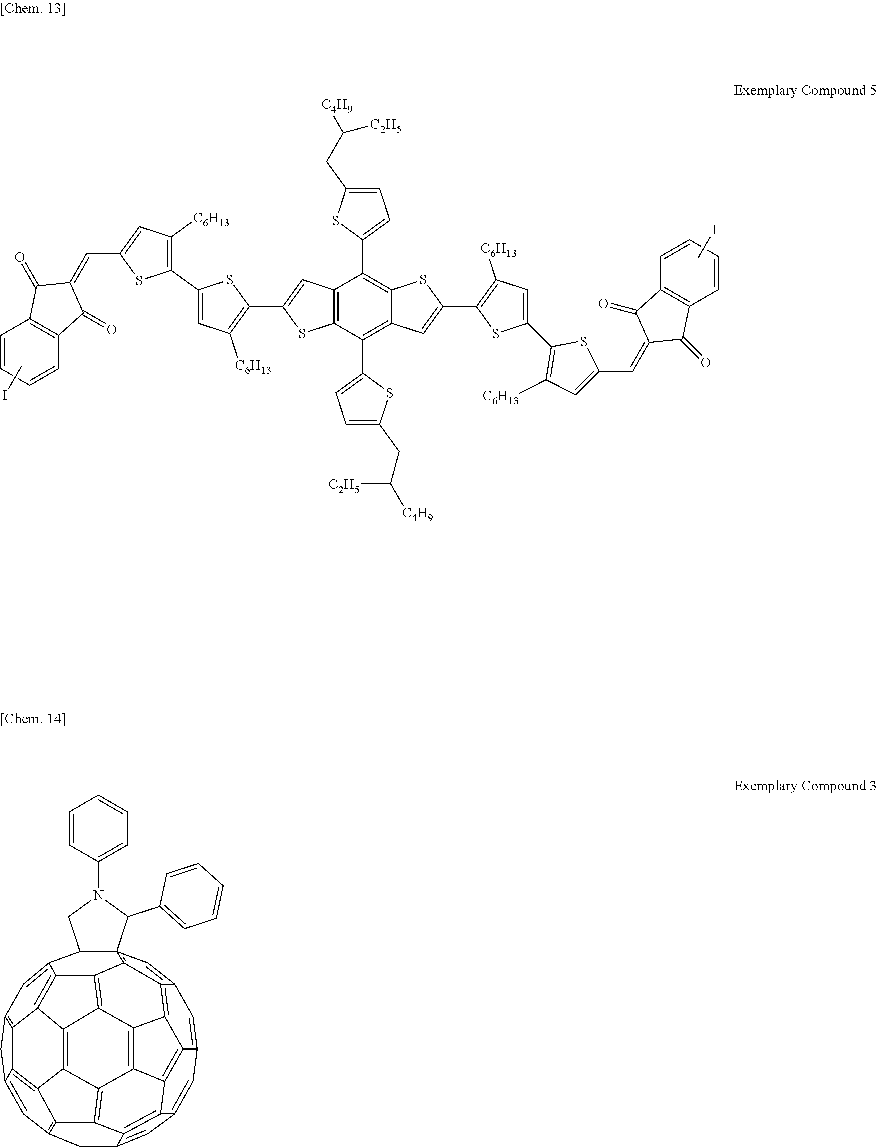

Next, the photoelectric conversion layer coating liquid E was spin-coated at 600 rpm on the intermediate layer to form a photoelectric conversion layer having an average thickness of 200 nm.

### Example 11

<Production of Photoelectric Conversion Element Module>

In the same manner as in Example 1 except that the photoelectric conversion layer coating liquid A was changed to the following photoelectric conversion layer coating liquid F, a photoelectric conversion element module was produced and evaluated. Results are presented in Table 1.

—Formation of Photoelectric Conversion Layer—

15 mg of Exemplary Compound 6 presented below (number average molecular weight (Mn): 1,886, highest occupied molecular orbital (HOMO) level: 5.00 eV) and 10 mg of Exemplary Compound 3 presented below were dissolved in 1 mL of chloroform to prepare photoelectric conversion layer coating liquid F.

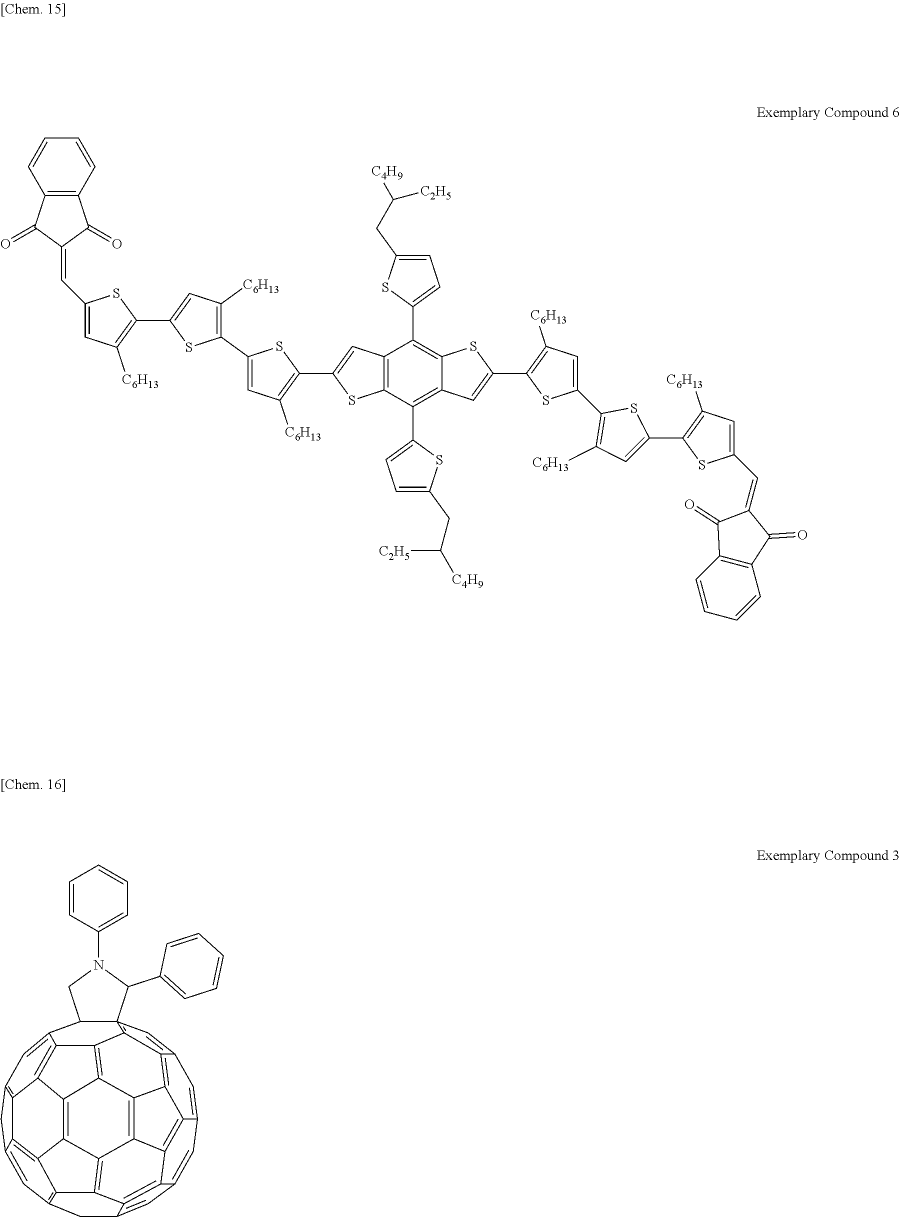

Next, the photoelectric conversion layer coating liquid F was spin-coated at 600 rpm on the intermediate layer to form a photoelectric conversion layer having an average thickness of 200 nm.

### Example 12

<Production of Photoelectric Conversion Element Module>

In the same manner as in Example 1 except that the photoelectric conversion layer coating liquid A was changed to the following photoelectric conversion layer coating liquid G, a photoelectric conversion element module was produced and evaluated. Results are presented in Table 1.

—Formation of Photoelectric Conversion Layer—

10 mg of polythiophene P3HT (obtained from Sigma Aldrich Co., number average molecular weight (Mn): 54,000) and 10 mg of fullerene derivative PC61BM (E100H, obtained from Frontier Carbon Corporation) were dissolved in 1 mL of chloroform to prepare photoelectric conversion layer coating liquid G.

Next, the photoelectric conversion layer coating liquid G was spin-coated at 600 rpm on the intermediate layer to form a photoelectric conversion layer having an average thickness of 200 nm.

### Example 13

<Production of Photoelectric Conversion Element Module>

In the same manner as in Example 1 except that the hole-transporting layer was changed to the following, a photoelectric conversion element module was produced and evaluated. Results are presented in Table 1.

—Formation of Hole-Transporting Layer and Formation of Second Electrode—

After deletion of the part coupled in series between the photoelectric conversion elements, P-30 (obtained from Avantama AG, PEDTT:PSS-containing molybdenum oxide nanoparticles dispersion liquid) was spin-coated on the photoelectric conversion layer to form a hole-transporting layer having an average thickness of 50 nm. Then, a second electrode of silver was formed through vacuum vapor deposition to have an average thickness of 100 nm.

### Example 14

<Production of Photoelectric Conversion Element Module>

In the same manner as in Example 1 except that the photoelectric conversion layer coating liquid A was changed to the following photoelectric conversion layer coating liquid H, a photoelectric conversion element module was produced and evaluated. Results are presented in Table 1.

—Formation of Photoelectric Conversion Layer—

14 mg of the Exemplary Compound 1, 10 mg of fullerene derivative PC61BM (E100H, obtained from Frontier Carbon Corporation), and 1 mg of PTB7-Th (obtained from Ossila Ltd., number average molecular weight (Mn): 57,000) were dissolved in 1 mL of chloroform to prepare photoelectric conversion layer coating liquid H.

Next, the photoelectric conversion layer coating liquid H was spin-coated at 600 rpm on the intermediate layer to form a photoelectric conversion layer having an average thickness of 200 nm.

### Example 15

<Production of Photoelectric Conversion Element Module>

In the same manner as in Example 1 except that the photoelectric conversion layer coating liquid A was changed to the following photoelectric conversion layer coating liquid I, a photoelectric conversion element module was produced and evaluated. Results are presented in Table 1.

—Formation of Photoelectric Conversion Layer—

14 mg of the Exemplary Compound 1, 10 mg of fullerene derivative PC61BM (E100H, obtained from Frontier Carbon Corporation), and 1 mg of PBDTTPD (obtained from Ossila Ltd., number average molecular weight (Mn): 38,000) were dissolved in 1 mL of chloroform to prepare photoelectric conversion layer coating liquid I.

Next, the photoelectric conversion layer coating liquid I was spin-coated at 600 rpm on the intermediate layer to form a photoelectric conversion layer having an average thickness of 200 nm.

### Example 16

<Production of Photoelectric Conversion Element Module>

In the same manner as in Example 1 except that the photoelectric conversion layer coating liquid A was changed to the following photoelectric conversion layer coating liquid J, a photoelectric conversion element module was produced and evaluated. Results are presented in Table 1.

—Formation of Photoelectric Conversion Layer—

14 mg of the Exemplary Compound 1, 10 mg of fullerene derivative PC61BM (E100H, obtained from Frontier Carbon Corporation), and 1 mg of PBDB-T (obtained from Brilliant Matters Co., number average molecular weight (Mn): 66,000) were dissolved in 1 mL of chloroform to prepare photoelectric conversion layer coating liquid J.

Next, the photoelectric conversion layer coating liquid J was spin-coated at 600 rpm on the intermediate layer to form a photoelectric conversion layer having an average thickness of 200 nm.

### Example 17

<Production of Photoelectric Conversion Element Module>

In the same manner as in Example 1 except that the electron-transporting layer was changed to the following, a photoelectric conversion element module was produced and evaluated. Results are presented in Table 1.

—Formation of Electron-Transporting Layer—

A liquid of Al-doped zinc oxide nanoparticles (obtained from Aldrich Co., average particle diameter: 12 nm) was spin-coated at 3,000 rpm on an ITO gas barrier PET film (15 Ω/sq.), followed by drying at 100 degrees Celsius at 10 minutes, to form an electron-transporting layer having an average thickness of 30 nm.

### Example 18

<Production of Photoelectric Conversion Element Module>

In the same manner as in Example 1 except that the hole-transporting layer was changed to the following, a photoelectric conversion element module was produced and evaluated. Results are presented in Table 1.

—Formation of Hole-Transporting Layer and Formation of Second Electrode—

After deletion of the part coupled in series between the photoelectric conversion elements, a hole-transporting layer having an average thickness of 50 nm was formed on the photoelectric conversion layer using tungsten oxide (obtained from Kojundo Chemical Lab. Co., Ltd.).

Then, a second electrode of silver was formed to have an average thickness of 100 nm. The hole-transporting layer and the second electrode were formed through vacuum vapor deposition.

### Example 19

<Production of Photoelectric Conversion Element Module>

In the same manner as in Example 1 except that the hole-transporting layer was changed to the following, a photoelectric conversion element module was produced and evaluated. Results are presented in Table 1.

—Formation of Hole-Transporting Layer and Formation of Second Electrode—

After deletion of the part coupled in series between the photoelectric conversion elements, a hole-transporting layer having an average thickness of 50 nm was formed on the photoelectric conversion layer using vanadium oxide (obtained from Kojundo Chemical Lab. Co., Ltd.). Then, a second electrode of silver was formed to have an average thickness of 100 nm. The hole-transporting layer and the second electrode were formed through vacuum vapor deposition.

### Example 20

<Production of Photoelectric Conversion Element Module>

In the same manner as in Example 1 except that the hole-transporting layer was changed to the following, a photoelectric conversion element module was produced and evaluated. Results are presented in Table 1.

—Formation of Hole-Transporting Layer and Formation of Second Electrode—

After deletion of the part coupled in series between the photoelectric conversion elements, a hole-transporting layer having an average thickness of 50 nm was formed on the photoelectric conversion layer using molybdenum oxide (obtained from Kojundo Chemical Lab. Co., Ltd.). Then, a second electrode of gold was formed to have an average thickness of 100 nm. The hole-transporting layer and the second electrode were formed through vacuum vapor deposition.

### Example 21

<Production of Photoelectric Conversion Element Module>

In the same manner as in Example 1 except that the first electrode was changed to the following, a photoelectric conversion element module was produced and evaluated. Results are presented in Table 1.

—Base with First Electrode—

A polyethylene terephthalate (PET) substrate (50 mm×50 mm) with a patterned gas barrier film was purchased from GEOMATEC Co., Ltd. This substrate had a stacked structure of indium-doped tin oxide (ITO)/silver/ITO.

### Comparative Example 1

<Production of Photoelectric Conversion Element Module>

In the same manner as in Example 1 except that the hole-transporting layer was not formed to form a photoelectric conversion element, a photoelectric conversion element module was produced and evaluated. Results are presented in Table 1.

—Formation of Hole-Transporting Layer and Formation of Second Electrode—

After deletion of the part coupled in series between the photoelectric conversion elements, a second electrode of silver was formed through vacuum vapor deposition to have an average thickness of 100 nm without forming a hole-transporting layer on the photoelectric conversion layer.

### Comparative Example 2

<Production of Photoelectric Conversion Element Module>

In the same manner as in Example 1 except that the electron-transporting layer was not formed, a photoelectric conversion element module was produced and evaluated. Results are presented in Table 1.

—Formation of Electron-Transporting Layer and Formation of Intermediate Layer—

An electron-transporting layer was not formed on an ITO gas barrier PET film (15 Ω/sq.). Instead, an intermediate layer of less than 10 nm was formed by dissolving dimethylaminobenzoic acid (obtained from Tokyo Chemical Industry Co., Ltd.) in ethanol to prepare a 1 mg/ml solution and spin-coating the solution at 3,000 rpm on the ITO gas barrier PET film.

### Comparative Example 3

<Production of Photoelectric Conversion Element Module>

In the same manner as in Example 1 except that deletion of the part coupled in series was performed after the formation of the hole-transporting layer, a photoelectric conversion element module was produced and evaluated. Results are presented in Table 1.

—Formation of Hole-Transporting Layer and Formation of Second Electrode—

A hole-transporting layer of molybdenum oxide (obtained from Kojundo Chemical Lab. Co., Ltd.) was vapor-deposited under vacuum on the photoelectric conversion layer to have an average thickness of 50 nm. A photoelectric conversion element was taken out from a vacuum vapor deposition apparatus. After deletion of the part coupled in series between the photoelectric conversion elements, a second electrode of silver was formed through vacuum vapor deposition to have an average thickness of 100 nm.

### Comparative Example 4

<Production of Photoelectric Conversion Element Module>

In the same manner as in Comparative Example 3 except that the thickness of the hole-transporting layer was changed to an average thickness of 10 nm, a photoelectric conversion element module was produced and evaluated. Results are presented in Table 1.

—Formation of Hole-Transporting Layer and Formation of Second Electrode—

A hole-transporting layer of molybdenum oxide (obtained from Kojundo Chemical Lab. Co., Ltd.) was vapor-deposited under vacuum on the photoelectric conversion layer to have an average thickness of 10 nm. A photoelectric conversion element was taken out from a vacuum vapor deposition apparatus. After deletion of the part coupled in series between the photoelectric conversion elements, a second electrode of silver was formed through vacuum vapor deposition to have an average thickness of 100 nm.

### Comparative Example 5

<Production of Photoelectric Conversion Element Module>

In the same manner as in Comparative Example 3 except that the thickness of the hole-transporting layer was changed to an average thickness of 200 nm, a photoelectric conversion element module was produced and evaluated. Results are presented in Table 1.

—Formation of Hole-Transporting Layer and Formation of Second Electrode—

A hole-transporting layer of molybdenum oxide (obtained from Kojundo Chemical Lab. Co., Ltd.) was vapor-deposited under vacuum on the photoelectric conversion layer to have an average thickness of 200 nm. A photoelectric conversion element was taken out from a vacuum vapor deposition apparatus. After deletion of the part coupled in series between the photoelectric conversion elements, a second electrode of silver was formed through vacuum vapor deposition to have an average thickness of 100 nm.

TABLE 1

| | | Evaluation Results | | |
|---|---|---|---|---|
| | | Initial | Relative time of | Solar |
| | | photoelectric | production | cell |
| | | conversion | process | characteristics |
| | | efficiency | (vs. Example 3) | (over time) |
| Examples | 1 | 12.10% | 0.76 | 96% |
| | 2 | 11.60% | 0.84 | 93% |
| | 3 | 11.30% | 1 | 92% |
| | 4 | 8.80% | 1.16 | 88% |
| | 5 | 12.60% | 0.7 | 95% |
| | 6 | 12.00% | 0.73 | 96% |
| | 7 | 13.50% | 0.76 | 93% |
| | 8 | 11.00% | 0.76 | 94% |
| | 9 | 9.40% | 0.76 | 86% |
| | 10 | 12.20% | 0.76 | 96% |
| | 11 | 11.40% | 0.76 | 96% |
| | 12 | 7.00% | 0.76 | 90% |
| | 13 | 9.90% | 0.69 | 81% |
| | 14 | 10.40% | 0.76 | 86% |
| | 15 | 11.00% | 0.76 | 90% |
| | 16 | 14.40% | 0.76 | 95% |
| | 17 | 12.90% | 0.76 | 96% |
| | 18 | 10.00% | 0.76 | 97% |
| | 19 | 10.00% | 0.76 | 96% |
| | 20 | 12.70% | 0.76 | 98% |
| | 21 | 12.00% | 0.76 | 96% |
| Comp. | 1 | 4.10% | 0.68 | 96% |
| Exs. | 2 | 3.00% | 0.76 | 96% |
| | 3 | 12.00% | 1.38 | 95% |
| | 4 | 12.60% | 1.32 | 93% |
| | 5 | 11.60% | 1.61 | 90% |

From the results of Table 1, it is found that the photoelectric conversion element of the present disclosure, which includes a hole-transporting layer between the first electrode and the second electrode in the penetration portion interior at the part coupled in series, can exhibit photoelectric conversion characteristics and maintain photoelectric conversion characteristics over time even when the hole-transporting layer is in contact with the other layers. This indicates that the photoelectric conversion element of the present disclosure can be produced through a shorter production process while maintaining photoelectric conversion characteristics comparable to those of the existing photoelectric conversion elements.

Aspects of the present disclosure are as follows, for example.

<1> A photoelectric conversion element including:

a base;

a first electrode on or above the base;

an electron-transporting layer on or above the first electrode;

a photoelectric conversion layer on or above the electron-transporting layer;

a hole-transporting layer on or above the photoelectric conversion layer; and

a second electrode on or above the hole-transporting layer,

the photoelectric conversion element having a penetration portion penetrating the electron-transporting layer and the photoelectric conversion layer,

the photoelectric conversion element including, in the penetration portion, a material of the hole-transporting layer and a material of the second electrode.

<2> The photoelectric conversion element according to <1>, wherein the material of the hole-transporting layer in the penetration portion is in contact with the electron-transporting layer.

<3> The photoelectric conversion element according to <1> or <2>, wherein the material of the hole-transporting layer in the penetration portion is in contact with the photoelectric conversion layer.

<4> The photoelectric conversion element according to any one of <1> to <3>, wherein the material of the hole-transporting layer in the penetration portion is in contact with the first electrode.

<5> A photoelectric conversion element including:

a base;

a first electrode on or above the base;

an electron-transporting layer on or above the first electrode;

a photoelectric conversion layer on or above the electron-transporting layer;

a hole-transporting layer on or above the photoelectric conversion layer; and

a second electrode on or above the hole-transporting layer,

wherein the second electrode is extended so as to penetrate the hole-transporting layer and the photoelectric conversion layer in a stacking direction, and

the second electrode, which is extended in the stacking direction, and the first electrode are coupled to each other via a hole-transporting material in contact with the electron-transporting layer.

<6> The photoelectric conversion element according to any one of <1> to <5>, wherein the hole-transporting layer has an average thickness of 200 nm or less.

<7> The photoelectric conversion element according to any one of <1> to <6>, wherein the hole-transporting layer includes at least one selected from the group consisting of molybdenum oxide, tungsten oxide, and vanadium oxide.

<8> The photoelectric conversion element according to any one of <1> to <7>, wherein the photoelectric conversion layer includes two or more kinds of organic materials and at least one of the organic materials is an electron-donating organic material, and

the electron-donating organic material has a highest occupied molecular orbital (HOMO) level of 5.1 eV or higher but 5.5 eV or lower and a number average molecular weight (Mn) of 10,000 or lower.

<9> The photoelectric conversion element according to <8>, wherein the organic materials include a compound represented by General Formula (2) below:

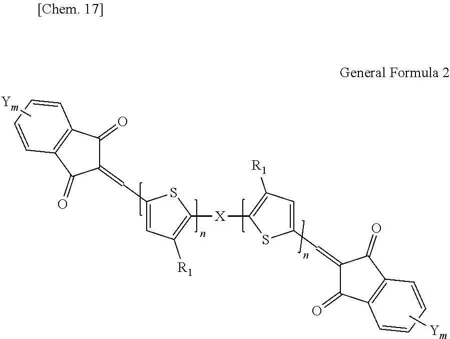

where in the General Formula (2), R₁ represents an alkyl group having from 2 through 8 carbon atoms, n represents an integer of 1 or 2, X represents General Formula (3) below or General Formula (4) below, Y represents a halogen atom, and m represents an integer of from 0 through 4,

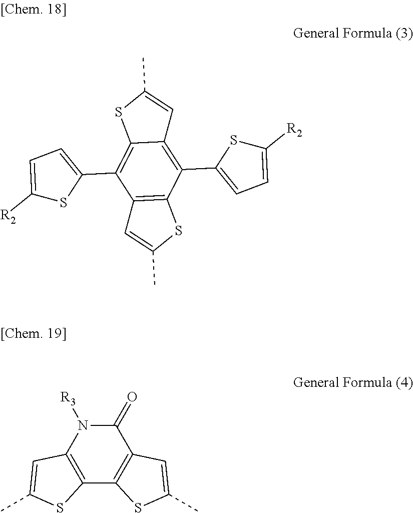

where in the General Formula (3) and the General Formula (4), R₂ and R₃ each represent a straight chain or branched alkyl group.

<10> The photoelectric conversion element according to any one of <1> to <9>, wherein the photoelectric conversion layer includes three or more kinds of organic materials and at least two of the organic materials are electron-donating organic materials,

one of the electron-donating organic materials has a highest occupied molecular orbital (HOMO) level of 5.1 eV or higher but 5.5 eV or lower and a number average molecular weight (Mn) of 10,000 or lower, and another or other of the electron-donating organic materials is an organic material having a highest occupied molecular orbital (HOMO) level of 5.1 eV or higher but 5.5 eV or lower, where the organic material has a repeating unit and has a number average molecular weight (Mn) of 10,000 or higher.

<11> The photoelectric conversion element according to any one of <8> to <10>, wherein the organic materials include a fullerene derivative.

<12> The photoelectric conversion element according to any one of <1> to <11>, wherein the electron-transporting layer includes a first electron-transporting layer containing particles of a metal oxide and a second electron-transporting layer between the first electron-transporting layer and the photoelectric conversion layer,

the second electron-transporting layer contains an amine compound represented by General Formula (1) below:

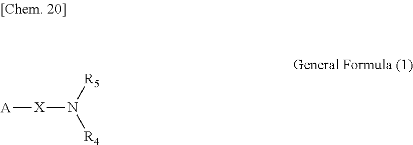

where in the General Formula (1), R₄ and R₅ each represent a substituted or non-substituted alkyl group having from 1 through 4 carbon atoms, X represents a divalent aromatic group having from 6 through 14 carbon atoms or an alkyl group having from 1 through 4 carbon atoms, R₄ and R₅ may be bonded to form a ring, and A represents one of substituents having structural formulas below:

—COOH

—P(═O)(OH)₂

—Si(OH)₃. [Chem. 21]

<13> A photoelectric conversion element module including:

photoelectric conversion elements coupled in series or in parallel,

wherein each of the photoelectric conversion elements is the photoelectric conversion element according to any one of <1> to <12>.

<14> An electronic device including:

at least one of the photoelectric conversion element according to any one of <1> to <12> and the photoelectric conversion element module according to <13>; and

a device configured to be driven by electric power generated through photoelectric conversion of the at least one of the photoelectric conversion element and the photoelectric conversion element module.

<15> An electronic device including:

at least one of the photoelectric conversion element according to any one of <1> to <12> and the photoelectric conversion element module according to <13>;

an electricity storage cell configured to store electric power generated through photoelectric conversion of the at least one of the photoelectric conversion element and the photoelectric conversion element module; and

a device configured to be driven by at least one of: the electric power generated through photoelectric conversion of the at least one of the photoelectric conversion element and the photoelectric conversion element module; and the electric power stored in the electricity storage cell.

<16> A power supply module including:

at least one of the photoelectric conversion element according to any one of <1> to <12> and the photoelectric conversion element module according to <13>; and

a power supply integrated circuit.

<17> A method for producing a photoelectric conversion element, the method including: an electron-transporting layer forming step of forming an electron-transporting layer on an exposed surface of a first electrode;

a photoelectric conversion layer forming step of forming a photoelectric conversion layer on an exposed surface of the electron-transporting layer;

a penetration portion forming step of forming a penetration portion penetrating the electron-transporting layer on the first electrode and the photoelectric conversion layer on the electron-transporting layer;

a hole-transporting layer forming step of forming a hole-transporting layer on the exposed surface of the first electrode, the exposed surface of the electron-transporting layer, and an exposed surface of the photoelectric conversion layer; and

a second electrode forming step of forming a second electrode on an exposed surface of the hole-transporting layer.

The photoelectric conversion element according to any one of <1> to <12>, the photoelectric conversion element module according to <13>, the electronic device according to <14> or <15>, the power supply module according to <16>, and the method for producing a photoelectric conversion element according to <17> can solve the existing problems and achieve the object of the present disclosure.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

This patent application is based on and claims priority to Japanese Patent Application No. 2020-117458, filed on Jul. 8, 2020, in the Japan Patent Office, the entire disclosure of which is hereby incorporated by reference herein.

### REFERENCE SIGNS LIST

10 photoelectric conversion element, photoelectric conversion element module
11 base
12 first electrode
12′, 12″ separation part
13 electron-transporting layer
14 intermediate layer (second electron-transporting layer)
15 photoelectric conversion layer
16 penetration portion
17 hole-transporting layer
18 second electrode
19 insulating layer
21 sealing layer
22 UV cut layer
23 gas barrier layer

1. A photoelectric conversion element comprising:
a base;
a first electrode on or above the base;
an electron-transporting layer on or above the first electrode;
a photoelectric conversion layer on or above the electron-transporting layer;
a hole-transporting layer on or above the photoelectric conversion layer; and
a second electrode on or above the hole-transporting layer,
wherein the photoelectric conversion element having a penetration portion penetrating the electron-transporting layer and the photoelectric conversion layer, and
wherein the photoelectric conversion element comprising, in the penetration portion, a material of the hole-transporting layer and a material of the second electrode.

2. The photoelectric conversion element according to claim 1, wherein the material of the hole-transporting layer in the penetration portion is in contact with the electron-transporting layer.

3. The photoelectric conversion element according to claim 1, wherein the material of the hole-transporting layer in the penetration portion is in contact with the photoelectric conversion layer.

4. The photoelectric conversion element according to claim 1, wherein the material of the hole-transporting layer in the penetration portion is in contact with the first electrode.

5. A photoelectric conversion element comprising:
a base;
a first electrode on or above the base;
an electron-transporting layer on or above the first electrode;
a photoelectric conversion layer on or above the electron-transporting layer;
a hole-transporting layer on or above the photoelectric conversion layer; and
a second electrode on or above the hole-transporting layer,
wherein the second electrode is extended so as to penetrate the hole-transporting layer and the photoelectric conversion layer in a stacking direction, and
wherein the second electrode, which is extended in the stacking direction, and the first electrode are coupled to each other via a hole-transporting material in contact with the electron-transporting layer.

6. The photoelectric conversion element according to claim 1, wherein the hole-transporting layer has an average thickness of 200 nm or less.

7. The photoelectric conversion element according to claim 1, wherein the hole-transporting layer comprises at least one selected from the group consisting of molybdenum oxide, tungsten oxide, and vanadium oxide.

8. The photoelectric conversion element according to claim 1, wherein the photoelectric conversion layer comprises two or more kinds of organic materials and at least one of the organic materials is an electron-donating organic material, and
the electron-donating organic material has a highest occupied molecular orbital (HOMO) level of 5.1 eV or higher but 5.5 eV or lower and a number average molecular weight (Mn) of 10,000 or lower.

9. The photoelectric conversion element according to claim 8, wherein the organic materials comprise a compound represented by General Formula (2) below: 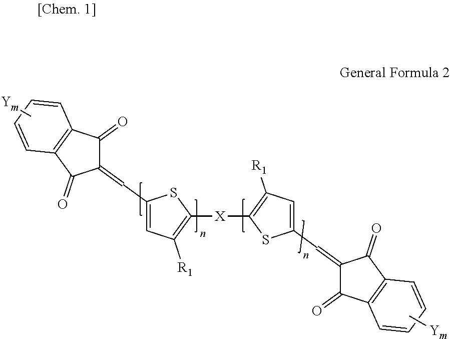
where in the General Formula (2), R₁ represents an alkyl group having from 2 through 8 carbon atoms, n represents an integer of 1 or 2, X represents General Formula (3) below or General Formula (4) below, Y represents a halogen atom, and m represents an integer of from 0 through 4, 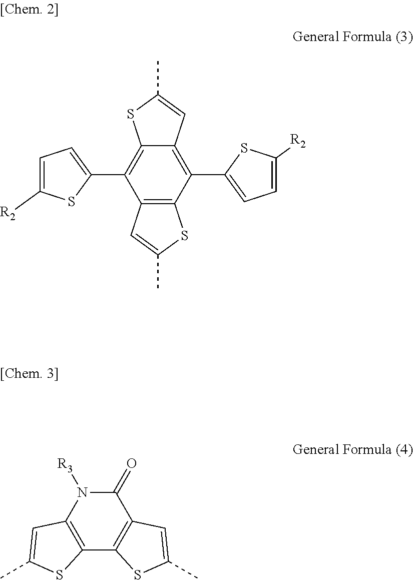
where in the General Formula (3) and the General Formula (4), R₂ and R₃ each represent a straight chain or branched alkyl group.

10. The photoelectric conversion element according to claim 1, wherein the photoelectric conversion layer comprises three or more kinds of organic materials and at least two of the organic materials are electron-donating organic materials,
one of the electron-donating organic materials has a highest occupied molecular orbital (HOMO) level of 5.1 eV or higher but 5.5 eV or lower and a number average molecular weight (Mn) of 10,000 or lower, and another or other of the electron-donating organic materials is an organic material having a highest occupied molecular orbital (HOMO) level of 5.1 eV or higher but 5.5 eV or lower, where the organic material has a repeating unit and has a number average molecular weight (Mn) of 10,000 or higher.

11. The photoelectric conversion element according to claim 8, wherein the organic materials comprise a fullerene derivative.

12. The photoelectric conversion element according to claim 1, wherein the electron-transporting layer comprises a first electron-transporting layer containing particles of a metal oxide and a second electron-transporting layer between the first electron-transporting layer and the photoelectric conversion layer,
the second electron-transporting layer comprises an amine compound represented by General Formula (1) below: 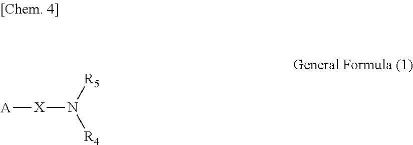
where in the General Formula (1), R₄ and R₅ each represent a substituted or non-substituted alkyl group having from 1 through 4 carbon atoms, X represents a divalent aromatic group having from 6 through 14 carbon atoms or an alkyl group having from 1 through 4 carbon atoms, R₄ and R₅ may be bonded to form a ring, and A represents one of substituents having structural formulas below:
—COOH
—P(═O)(OH)₂
—Si(OH)₃. [Chem. 5]

13. A photoelectric conversion element module comprising:
photoelectric conversion elements coupled in series or in parallel,
wherein each of the photoelectric conversion elements is the photoelectric conversion element according to claim 1.

14. An electronic device comprising:
a photoelectric conversion element module including a plurality of the photoelectric conversion element of claim 1 coupled in series or parallel; and
a device configured to be driven by electric power generated through photoelectric conversion of the at least one of the photoelectric conversion element and the photoelectric conversion element module.

15. An electronic device comprising:
a photoelectric conversion element module including a plurality of the photoelectric conversion element of claim 1 coupled in series or parallel;
an electricity storage cell configured to store electric power generated through photoelectric conversion of the at least one of the photoelectric conversion element and the photoelectric conversion element module; and
a device configured to be driven by at least one of: the electric power generated through photoelectric conversion of the at least one of the photoelectric conversion element and the photoelectric conversion element module; and the electric power stored in the electricity storage cell.

16. A power supply module comprising:
a photoelectric conversion element module including a plurality of the photoelectric conversion element of claim 1 coupled in series or parallel; and
a power supply integrated circuit.

17. A method for producing a photoelectric conversion element, the method comprising:
forming an electron-transporting layer on an exposed surface of a first electrode;
forming a photoelectric conversion layer on an exposed surface of the electron-transporting layer;
forming a penetration portion penetrating the electron-transporting layer on the first electrode and the photoelectric conversion layer on the electron-transporting layer;
forming a hole-transporting layer on the exposed surface of the first electrode, the exposed surface of the electron-transporting layer, and an exposed surface of the photoelectric conversion layer; and
forming a second electrode on an exposed surface of the hole-transporting layer.
